(19) United States
(12) Patent Application Publication
(10) Pub. No.: US 2006/0121714 A1
(43) Pub. Date: Jun. 8, 2006

(54) Semiconductor device and method for manufacturing the same

(75) Inventors: Hiroyuki Ohta, Kawasaki (JP); Katsuaki Ookoshi, Kawasaki (JP); Toshifumi Mori, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/103,562

(22) Filed: Apr. 12, 2005

(30) Foreign Application Priority Data
Dec. 3, 2004 (JP) 2004-350749

(51) Int. Cl. H01L 21/3205

(52) U.S. Cl. 438/595

(57) ABSTRACT

Disclosed is a method for manufacturing a semiconductor device provided with a sidewall having a high quality and an excellent shape. The sidewall on a gate electrode side wall is formed using a carbon-containing silicon nitride oxide film. The film can be formed by a CVD method using, as starting materials, BTBAS and oxygen where a BTBAS flow rate/oxygen flow rate ratio is appropriately set and a low film formation temperature is set, for example, at about 530° C. When forming the sidewall using this film, improvement in HF resistance and reduction in fringe capacitance can be realized due to contribution of nitrogen atoms and carbon atoms. Further, when forming this film under low temperature conditions, unnecessary diffusion of impurities introduced into a semiconductor substrate can be suppressed. Thus, transistor characteristics are enhanced and stabilized, so that high performance and high quality in the semiconductor device can be realized.

### CROSS-REFERENCE TO RELATED APPLICATIONS

This application is based upon and claims the benefits of priority from the prior Japanese Patent Application No. 2004-350749, filed on Dec. 3, 2004, the entire contents of which are incorporated herein by reference.

### BACKGROUND OF THE INVENTION

1. Field of the Invention

The present invention relates to a semiconductor device and a method for manufacturing the same. More particularly, the present invention relates to a semiconductor device comprising a gate electrode and a sidewall provided on the gate electrode. The invention also pertains to a method for manufacturing the same.

2. Description of the Related Art

In a semiconductor device, a sidewall is provided on a side wall of a gate electrode, and plays the roll of electrically separating a gate electrode and an impurity region within a transistor. The gate electrode is formed on a semiconductor substrate such as a silicon substrate. The impurity region such as a source/drain region or an extension region is formed within the substrate. For the sidewall, an insulating silicon oxide film (mainly, SiO₂) or silicon nitride film (mainly, Si₃N₄) or laminated film thereof is generally used. These films that configure the sidewall are heretofore formed using a Chemical Vapor Deposition (CVD) method. In the method, the film formation is heretofore performed under relatively higher temperature conditions to obtain a dense film.

However, when the film formation is performed under the high temperature conditions, the following problem arises. For example, impurities introduced into the gate electrode or the semiconductor substrate prior to the film formation are excessively diffused, which leads to reduction in transistor characteristics in some cases. Particularly, since miniaturization in the transistor structure proceeds in recent years, it is increasingly important to prevent such impurity diffusion in order to obtain a semiconductor device having high performance and high quality.

On the other hand, a method for forming a silicon oxide film or a silicon nitride film under lower temperature conditions is proposed (see, Japanese Unexamined Patent Publication No. 2004-153066). In the proposal, bis (tertiarybutylamino) silane (BTBAS) is used as a starting material in place of tetraethoxysilane (TEOS) or dichlorosilane (DCS) which is heretofore commonly used, whereby a lower temperature as the film formation conditions is realized.

In addition thereto, conventional examples of the method for forming a film by the CVD method using BTBAS as a starting material are a method for forming a silicon compound film containing nitrogen (see, Japanese Unexamined Patent Publication No. 2004-186210) or a method for forming a silicon oxide film containing carbon (see, Japanese Unexamined Patent Publication No. 2004-119980).

As described above, various methods for forming a film such as a silicon oxide film or a silicon nitride film are studied. However, when using the film as a sidewall, the following problems remain.

For example, when using the silicon nitride film for the whole part or a part of the sidewall, the following problems are caused irrespective of the film formation method. Since a dielectric constant of the silicon nitride film is larger than that of the silicon oxide film, fringe capacitance readily occurs on the sidewall formed between the gate electrode and the impurity region, during the operation. The fringe capacitance contributes to the prevention of speeding up of transistors. Further, since the silicon nitride film is usually formed under higher temperature conditions as compared with the silicon oxide film, impurities are excessively diffused. Accordingly, the silicon oxide film which can be formed under lower temperature conditions is more preferably used for the sidewall in terms of reducing the fringe capacitance and avoiding the problem of impurity diffusion as described above as much as possible.

However, also when using the silicon oxide film for the sidewall, the following problems are caused. In general, the sidewall is formed, for example, by the following method. Ion implantation is first performed for forming an extension region within the silicon substrate in which the gate electrode is formed through the gate insulating film. Then, the silicon oxide film is formed on the whole surface of the substrate and subjected to dry etching using a fluorocarbon gas, whereby the sidewall is formed. Thereafter, using the sidewall as a mask, ion implantation for forming a source/drain region within the silicon substrate is performed, followed by performing Rapid Thermal Annealing (RTA) and if desired, silicification. When performing the silicification, a pretreatment thereof is performed. More specifically, a treatment of cleaning the silicon substrate surface is performed by removing, using a hydrofluoric acid (HF) solution, a native oxide film produced on the silicon substrate or carbon remaining after the dry etching.

FIG. 39 is a schematic cross-sectional view of an essential part after an HF treatment.

FIG. 39 shows a transistor structure formed as follows. On a silicon substrate 100, a gate electrode 102 is formed through a gate insulating film 101. On a side wall of the gate electrode, a sidewall 103 is provided. Thereafter, an extension region 104 and a source/drain region 105 are formed within the silicon substrate 100. The broken line in the figure shows a shape of the sidewall 103 before the HF treatment.

In the case of forming the sidewall 103 by using a silicon oxide film, when the HF treatment for removing a native oxide film is performed, a part of the sidewall 103 also is qualitatively etched with the HF solution. As a result, as indicated by an arrow in the figure, the sidewall 103 largely recedes toward the gate electrode 102 side as compared with the shape (the broken line in the figure) of the sidewall 103 before the HF treatment.

The recession of the sidewall 103 causes such a problem that leakage readily occurs between the gate electrode 102 and the source/drain region 105. This is because a distance along a surface of the sidewall 103 between the gate electrode 102 and the source/drain region 105 is reduced due to recession of the sidewall 103. When a metal such as cobalt (Co) used in the silicification remains even in a small amount on the sidewall 103 surface, the problem readily occurs particularly.

The problem caused by the recession of the sidewall 103 due to the HF treatment may be avoided by a method where the silicon oxide film serving as the sidewall 103 is formed under high temperature conditions to obtain a dense film. In this case, however, the problem of impurity diffusion as described above may occur, which is likely to cause reduction in transistor characteristics. Further, these problems such as recession of the sidewall 103 due to the HF treatment or impurity diffusion due to the high temperature treatment become more remarkable as the transistor is more miniaturized.

### SUMMARY OF THE INVENTION

In view of the foregoing, it is an object of the present invention to provide a method for manufacturing a high-performance and high-quality semiconductor device comprising a gate electrode, and a sidewall provided on the gate electrode, and to provide the semiconductor device.

To accomplish the above object, according to one aspect of the present invention, there is provided a method for manufacturing a semiconductor device comprising a gate electrode and a sidewall provided on the gate electrode, comprising the steps of: forming the gate electrode on a semiconductor substrate through a gate insulating film; forming one sidewall on a part that comes in contact with a side wall of the gate electrode; forming other sidewalls on a part that is outside the one sidewall and that serves as a surface of the one sidewall; and introducing impurities into the semiconductor substrate using the other sidewalls as masks to form an impurity region within the substrate, wherein among the one sidewall and the other sidewalls, at least the other sidewalls are formed using a carbon-containing silicon nitride oxide film.

According to another aspect of the present invention, there is provided a semiconductor device comprising: a gate electrode, and a sidewall provided on the gate electrode, wherein the sidewall is formed using a carbon-containing silicon nitride oxide film and the carbon-containing silicon nitride oxide film is formed on at least a part serving as a surface of the sidewall.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows a film formation mechanism of a carbon-containing silicon nitride oxide film.

FIG. 2 is a schematic cross-sectional view showing a part of a carbon-containing silicon nitride oxide film formed on a semiconductor substrate.

FIG. 3 shows one example of infrared spectra.

FIG. 4 shows one example of composition analysis results of a carbon-containing silicon nitride oxide film.

FIG. 5 shows a relation between a refractive index and an HF etching rate.

FIG. 6 shows a relation between a refractive index and an etching amount.

FIG. 7 shows a relation between a refractive index and dielectric constant of a silicon nitride oxide film.

FIG. 8 is an outline schematic view of a transistor arrangement within an SRAM memory cell.

FIG. 9 is a schematic cross-sectional view of a shared contact structure.

FIG. 10 illustrates problems which may occur in a shared contact structure.

FIG. 11 is a schematic cross-sectional view of a pattern end in forming a sidewall using a carbon-containing silicon nitride oxide film.

FIG. 12 is a schematic cross-sectional view of a pattern central part in forming a sidewall using a carbon-containing silicon nitride oxide film.

FIG. 13 is a schematic cross-sectional view of a pattern end in forming a sidewall using a silicon oxide film.

FIG. 14 is a schematic cross-sectional view of an essential part in a forming step of a resist pattern for a trench.

FIG. 15 is a schematic cross-sectional view of an essential part in a forming step of a trench.

FIG. 16 is a schematic cross-sectional view of an essential part in an oxidizing step of a trench side wall.

FIG. 17 is a schematic cross-sectional view of an essential part in a forming step of a buried oxide film.

FIG. 18 is a schematic cross-sectional view of an essential part in planarizing and annealing steps.

FIG. 19 is a schematic cross-sectional view of an essential part in a removing step of a silicon nitride film.

FIG. 20 is a schematic cross-sectional view of an essential part in a forming step of a well region and a gate insulating film.

FIG. 21 is a schematic cross-sectional view of an essential part in a forming step of polycrystalline silicon film.

FIG. 22 is a schematic cross-sectional view of an essential part in a forming step of a resist pattern for a gate electrode.

FIG. 23 is a schematic cross-sectional view of an essential part in a forming step of a gate electrode.

FIG. 24 is a schematic cross-sectional view of an essential part in a forming step of a first sidewall.

FIG. 25 is a schematic cross-sectional view of an essential part in a forming step of a shallow impurity region of an n MOS transistor.

FIG. 26 is a schematic cross-sectional view of an essential part in a forming step of a shallow impurity region of a p MOS transistor.

FIG. 27 is a schematic cross-sectional view of an essential part in a forming step of a second sidewall.

FIG. 28 is a schematic cross-sectional view of an essential part in a forming step of a first source/drain region of an n MOS transistor.

FIG. 29 is a schematic cross-sectional view of an essential part in a forming step of a first source/drain region of a p MOS transistor.

FIG. 30 is a schematic cross-sectional view of an essential part in a forming step of a third sidewall.

FIG. 31 is a schematic cross-sectional view of an essential part in a forming step of a second source/drain region.

FIG. 32 is a schematic cross-sectional view of an essential part in a silicification step.

FIG. 33 is a schematic cross-sectional view (part 1) of an essential part, which illustrates an application example of a carbon-containing silicon nitride oxide film.

FIG. 34 is a schematic cross-sectional view (part 2) of an essential part, which illustrates an application example of a carbon-containing silicon nitride oxide film.

FIG. 35 is a schematic cross-sectional view of an essential part, which illustrates an application example of a carbon-containing silicon nitride oxide film to a sidewall having a double structure.

FIG. 36 is a schematic cross-sectional view (part 1) of an essential part, which illustrates another application example of a carbon-containing silicon nitride oxide film.

FIG. 37 is a schematic cross-sectional view (part 2) of an essential part, which illustrates another application example of a carbon-containing silicon nitride oxide film.

FIG. 38 is a schematic cross-sectional view (part 3) of an essential part, which illustrates another application example of a carbon-containing silicon nitride oxide film.

FIG. 39 is a schematic cross-sectional view of an essential part after an HF treatment.

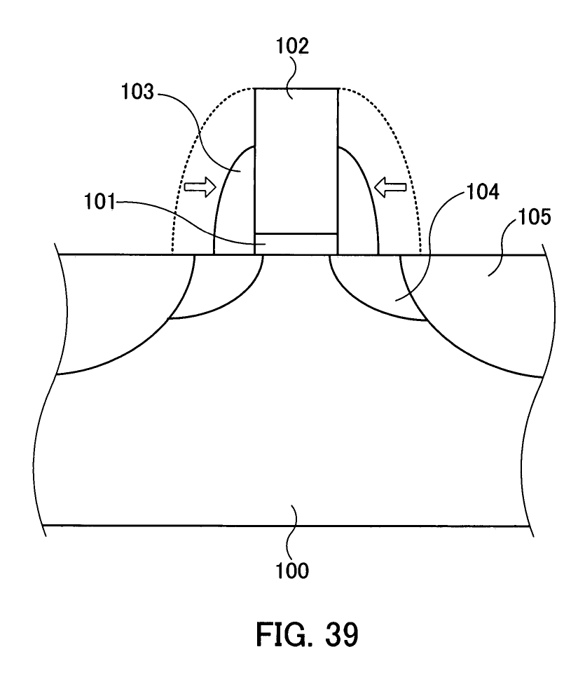

### DESCRIPTION OF THE PREFERRED EMBODIMENTS

Preferred embodiments of the present invention will be described below with reference to the accompanying drawings, wherein like reference numerals refer to like elements throughout.

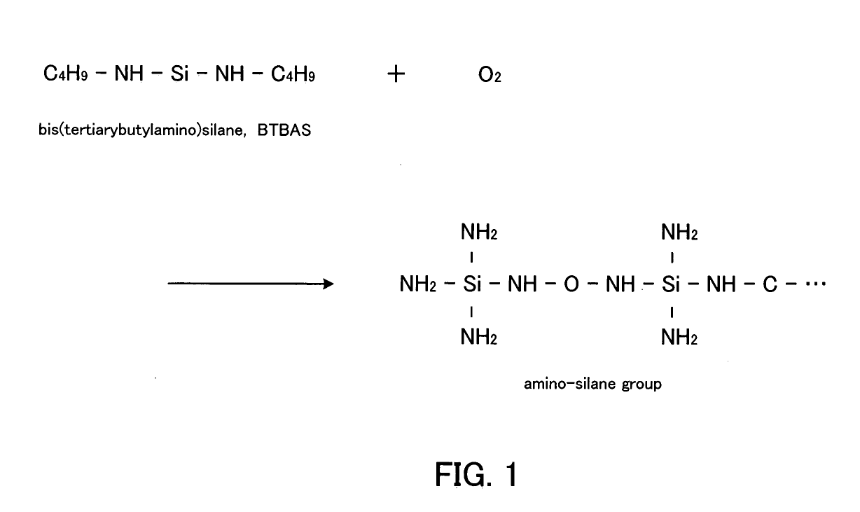

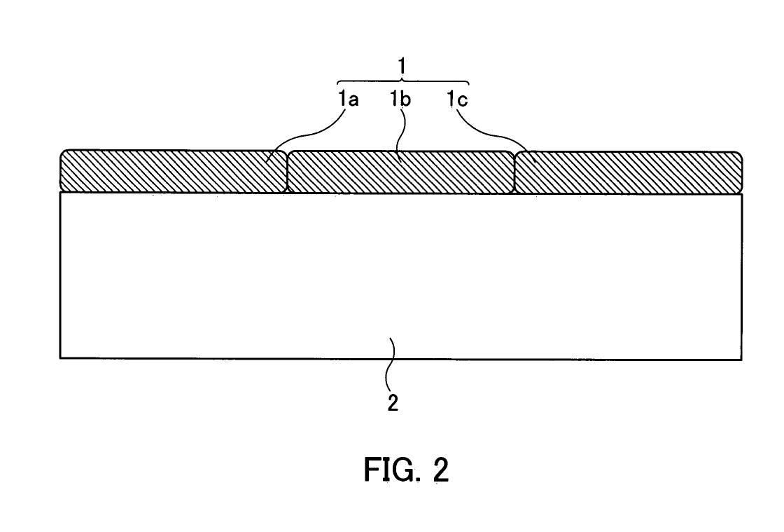

FIG. 1 shows a film formation mechanism of a carbon-containing silicon nitride oxide film. FIG. 2 is a schematic cross-sectional view showing a part of a carbon-containing silicon nitride oxide film formed on a semiconductor substrate.

As shown in FIG. 1, the carbon-containing silicon nitride oxide film can be formed using BTBAS and oxygen (O₂) as starting materials by a thermal CVD method under the following conditions. The pressure within the film formation room is set to about 0.1 to about 1000 Pa, preferably about 5 to about 100 Pa. The film formation temperature is set to low temperature conditions of about 300 to about 650° C., preferably about 450 to about 580° C. The film formation time is set according to the pressure within the film formation room or the film formation temperature.

Further, the BTBAS flow rate and oxygen flow rate during the film formation are appropriately set according to a type of usage (a type of application to the semiconductor device or specifications of the semiconductor device) of the carbon-containing silicon nitride oxide film. The reason is as follows. As a ratio between the BTBAS flow rate and the oxygen flow rate (the BTBAS flow rate/oxygen flow rate ratio) more decreases, the silicon oxide film is more readily formed. On the other hand, as a ratio between the BTBAS flow rate and the oxygen flow rate more increases, the carbon-containing silicon nitride oxide film is more readily formed.

For example, the following two cases are studied under the above-described conditions of the pressure within the film formation room and the film formation temperature. When the oxygen flow rate is set in the range of about 100 to about 300 sccm with respect to the BTBAS flow rate of about 20 sccm (standard cubic centimeter per minute), a Si—N bond within the BTBAS is cut off to form a Si—O bond. As a result, the silicon oxide film is mainly formed. On the other hand, when the oxygen flow rate is set in the range of about 0.1 to about 60 sccm with respect to the BTBAS flow rate of about 20 to about 400 sccm so as to increase the BTBAS flow rate/oxygen flow rate ratio, the Si—N bond or C—N bond within the BTBAS is likely to remain without being cut off. As a result, as shown in FIG. 1, a certain number of amino-silanes or molecules having a structure close to the amino-silane are bonded with each other through an oxygen atom (O) or a carbon atom (C) to form an amino-silane group.

However, a molecular composition of the amino-silane group varies according to the BTBAS flow rate/oxygen flow rate ratio. As the BTBAS flow rate/oxygen flow rate ratio more increases, more nitrogen atoms (N) remain. Further, a Si—O bond also is formed within the amino-silane group by the same film formation mechanism as that of the silicon oxide film (not shown).

As described above, in the formation of the amino-silane group, the BTBAS flow rate is set to about 20 to about 400 sccm, preferably about 80 to about 200 sccm. In addition, the oxygen flow rate is set to about 0.1 to about 60 sccm, preferably about 1 to about 20 sccm. More specifically, when the BTBAS flow rate/oxygen flow rate ratio is set to about 1/3 to about 4000, preferably about 4 to about 200, the amino-silane group is formed to allow formation of a preferable carbon-containing silicon nitride oxide film.

The reason why in the formation of the carbon-containing silicon nitride oxide, the BTBAS flow rate/oxygen flow rate ratio is set to about 1/3 to about 4000 is considered as follows. When the ratio is less than about 1/3 or is more than about 4000, there is a higher possibility that the after-mentioned advantageous characteristics as the carbon-containing silicon nitride oxide film cannot be ensured. Further, the reason why the film formation temperature is set in the range of about 300 to about 650° C. is considered as follows. When the temperature is less than about 300° C., it is difficult to form the carbon-containing silicon nitride oxide film having a preferable film quality. On the other hand, when the temperature is more than about 650° C., there is a higher possibility that unnecessary impurity diffusion will be caused during the formation of the carbon-containing silicon nitride oxide film.

Further, even when nitrous oxide (N₂O) or nitrogen monoxide (NO) is used in place of oxygen in the starting materials for forming the carbon-containing silicon nitride oxide film, the same reaction is caused to form the amino-silane group.

In the case of using BTBAS and nitrous oxide as the starting materials, when the BTBAS flow rate/nitrous oxide flow rate ratio is set to about 1/150 to about 8, preferably about 1/20 to about 2, the amino-silane group is formed to allow formation of a preferable carbon-containing silicon nitride oxide film. When the ratio is less than about 1/150 or is more than about 8, there is a higher possibility that the advantageous characteristics as the carbon-containing silicon nitride oxide film cannot be ensured. Further, the film formation temperature is set in a range under low temperature conditions of about 300 to about 700° C., in view of the film quality of the carbon-containing silicon nitride oxide film as well as occurrence of unnecessary impurity diffusion.

In the case of using BTBAS and nitrogen monoxide as the starting materials, when the BTBAS flow rate/nitrogen monoxide flow rate ratio is set to about 1/100 to about 20, preferably about 1/20 to about 2, the amino-silane group is formed to allow formation of a preferable carbon-containing silicon nitride oxide film. When the BTBAS flow rate/nitrogen monoxide flow rate ratio is less than about 1/150 or is more than about 8, there is a higher possibility that the advantageous characteristics as the carbon-containing silicon nitride oxide film cannot be ensured. Further, similarly to the case where nitrous oxide is used, the film formation temperature is set in a range under low temperature conditions of about 300 to about 700° C., in view of the film quality of the carbon-containing silicon nitride oxide film as well as occurrence of unnecessary impurity diffusion.

During the CVD, as shown in FIG. 2, each of amino-silane groups 1a, 1b and 1c is uniformly deposited on a silicon substrate 2 and as a result, a carbon-containing silicon nitride oxide film 1 is formed on the silicon substrate 2. Any of a carbon source, silicon source and nitrogen source of the carbon-containing silicon nitride oxide film are substantially BTBAS. Further, the amino-silane groups 1a, 1b and 1c configuring the carbon-containing silicon nitride oxide film 1 have good matching with the silicon substrate 2 as far as the film is formed at least under the above-described low temperature film formation conditions. Accordingly, for example, when forming the sidewall using the carbon-containing silicon nitride oxide film 1, a large interfacial level can be prevented from occurring between the sidewall and the silicon substrate 2.

FIG. 2 shows the only three amino-silane groups of 1a, 1b and 1c merely as examples. However, the fact is that a large number of amino-silane groups are deposited to configure the carbon-containing silicon nitride oxide film 1.

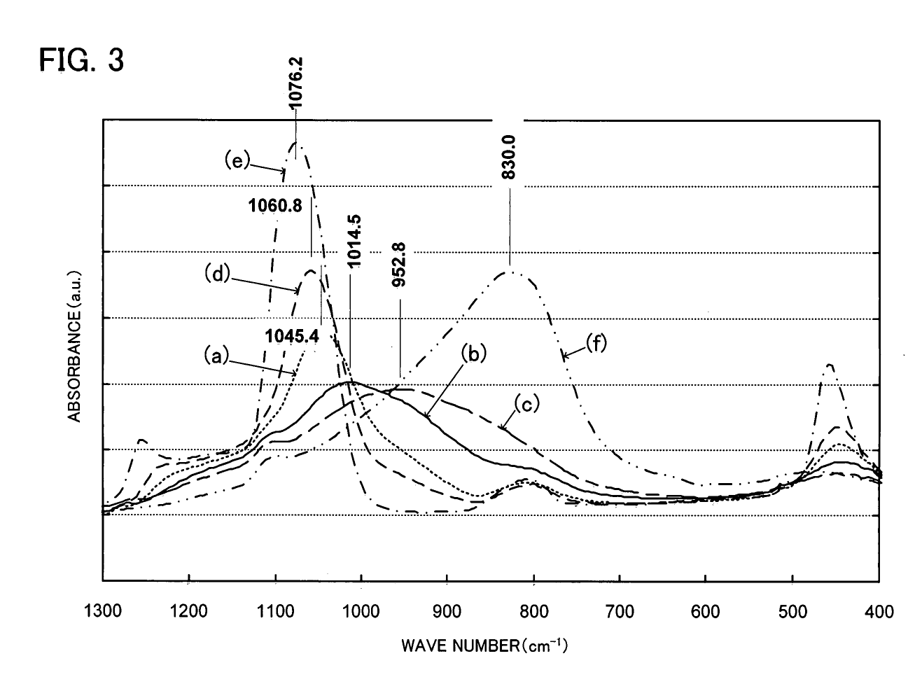

FIG. 3 shows one example of infrared spectra.

The Infrared spectra shown in FIG. 3 are obtained by Fourier Transform Infrared Spectroscopy. In FIG. 3, the horizontal axis shows a wave number (cm⁻¹) and the vertical axis shows an absorbance (a.u.). FIG. 3 shows IR spectra (a), (b) and (c) of various carbon-containing silicon nitride oxide films obtained by changing the BTBAS flow rate/oxygen flow rate ratio, an IR spectrum (d) of a silicon oxide film formed by using BTBAS and oxygen as starting materials, an IR spectrum (e) of a thermally-oxidized film formed on a silicon substrate surface by a thermal oxidation method, and an IR spectrum (f) of a silicon nitride film formed by using ammonia (NH₃) in place of oxygen in the starting materials.

Each film used for obtaining the IR spectra (a) to (f) is formed under the following conditions. First of all, films used for obtaining the IR spectra (a) to (d) are formed under the conditions that the pressure within the film formation room is set to about 10 Pa, the film formation temperature is set to about 530° C., and the BTBAS flow rate/oxygen flow rate ratio is set to about 5 in the spectrum (a), about 15 in the spectrum (b), about 30 in the spectrum (c) and about 1/4 in the spectrum (d). A film used for obtaining the IR spectrum (e) is formed by oxidizing the silicon substrate surface at a temperature of about 1000° C. A film used for obtaining the IR spectrum (f) is formed under the conditions that the pressure within the film formation room is set to about 10 Pa, the film formation temperature is set to about 600° C. and the BTBAS flow rate/ammonia flow rate ratio is set to about 1/4. Any film is formed to a thickness of about 90 nm.

From FIG. 3, the following facts are found. The IR spectrum (e) of the thermally-oxidized film has a relatively sharp peak at 1076.2 cm⁻¹. This peak shows presence of the Si—O bond. On the other hand, the IR spectrum (f) of the silicon nitride film is broad and has a peak at 830.0 cm⁻¹. This peak shows presence of the Si—N bond.

The IR spectrum (d) of the silicon oxide film also has a peak showing presence of the Si—O bond at 1060.8 cm⁻¹. On the other hand, the IR spectra (a), (b) and (c) of the carbon-containing silicon nitride oxide films become broader as the BTBAS flow rate/oxygen flow rate ratio more increase. Further, the IR spectra (a) , (b) and (c) have peaks at 1045 cm⁻¹, 1014.5 cm⁻¹ and 952.8 cm⁻, respectively, which are shifted to the low wave number side. As described above, the peaks of the IR spectra (a), (b) and (c) are present between the peak observed at 1076.2 cm⁻¹ in the IR spectrum (e) of the thermally-oxidized film, and the peak observed at 830.0 cm⁻¹ in the IR spectrum (f) of the silicon nitride film. Therefore, it can be said that the Si—O bond and the Si—N bond are present together in these carbon-containing silicon nitride oxide films.

Herein, the carbon-containing silicon nitride oxide film formed using BTBAS and oxygen as the starting materials is described. Also in both cases of using BTBAS and nitrous oxide as the starting materials and using BTBAS and nitrogen monoxide as the starting materials, each of the formed carbon-containing silicon nitride oxide films is a film where the Si—O bond and the Si—N bond are present together.

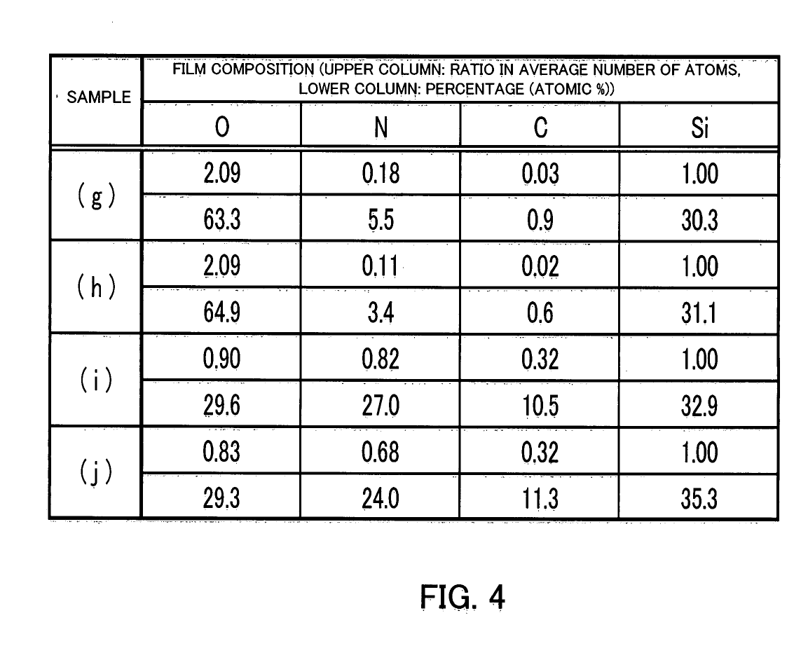

FIG. 4 shows one example of composition analysis results of the carbon-containing silicon nitride oxide film.

FIG. 4 shows the results of composition analysis performed on the following four types of films: (g) a silicon oxide film formed by setting the BTBAS flow rate/oxygen flow rate ratio to about 1/4, (h) a silicon oxide film obtained by subjecting the film (g) to ion implantation of phosphorus (P⁺) and boron (B⁺) suitable for the formation of a source/drain region and then subjecting it to RTA, (i) a carbon-containing silicon nitride oxide film formed by setting the BTBAS flow rate/oxygen flow rate ratio to about 30, and (j) a carbon-containing silicon nitride oxide film obtained by subjecting the film (i) to ion implantation of phosphorus (P⁺) and boron (B⁺) suitable for the formation of a source/drain region and then subjecting it to RTA.

In any case of the silicon oxide film and the carbon-containing silicon nitride oxide film, the ion implantation, the RTA process, and the film formation are performed under the following conditions. The ion implantation of phosphorus is performed under the conditions that an acceleration energy is about 10 keV and a dose amount is about 1×10¹⁶ cm⁻². The ion implantation of boron is performed under the conditions that an acceleration energy is about 3 keV and a dose amount is about 5×10¹⁵ cm⁻². The RTA process is performed for about 10 seconds at a temperature of about 1000° C. The film formation is performed under the conditions that the pressure within the film formation room is about 10 Pa, the film formation temperature is about 530° C., and the film thickness is about 90 nm.

The composition analysis is performed by combining a Nuclear Reaction Analysis (NRA) method and a Rutherford Back scattering Spectroscopy (RBS) method. FIG. 4 shows a ratio in the average number of atoms (upper column) contained in a film at the time when assuming that the number of silicon atoms is 1.0, and the percentage (lower column) of the atoms, for each of oxygen atoms (O), nitrogen atoms (N), carbon atoms (C) and silicon atoms (Si). The measurement accuracy in the composition analysis is as follows. In the case of the silicon oxide film, the measurement accuracy of an oxygen atom is ±5%, that of a nitrogen atom is ±100%, and that of a carbon atom is ±10% in terms of the ratio in the number of silicon atoms. In the case of the carbon-containing silicon nitride oxide film, the measurement accuracy of an oxygen atom is ±5%, that of a nitrogen atom is ±10%, and that of a carbon atom is ±5% in terms of the ratio in the number of silicon atoms.

From FIG. 4, the following facts can be confirmed. In the samples (g) and (h) of the silicon oxide films, the percentage of the carbon atoms is less than 1 atomic % irrespective of implementation of the ion implantation and the RTA. On the other hand, in the samples (i) and (j) of the carbon-containing silicon nitride oxide films, the percentage of the carbon atoms is equal to or more than 10 atomic % irrespective of implementation of the ion implantation and the RTA. Further, the carbon-containing silicon nitride oxide film decreases in the percentage of the oxygen atoms and increases in the percentage of the nitrogen atoms as compared with the silicon oxide film.

As described above, when performing the film formation by using BTBAS and oxygen as starting materials and by appropriately setting the BTBAS flow rate/oxygen flow rate ratio, the carbon-containing silicon nitride oxide film containing carbon atoms at a constant rate may be formed. Furthermore, also in the case of using nitrous oxide or nitrogen monoxide in place of oxygen, when performing the film formation by appropriately setting the BTBAS flow rate/nitrous oxide flow rate ratio or the BTBAS flow rate/nitrogen monoxide flow rate ratio, the carbon-containing silicon nitride oxide film containing carbon atoms at a constant rate may be formed.

The term “carbon-containing” means a case where carbon atoms are contained in the film at a constant rate as shown in a structural formula of the amino-silane group in FIG. 1 or in the composition analysis results in FIG. 4. When the term “containing no carbon atom” or the term “no carbon atom is contained” is used or when it is not particularly specified whether carbon atoms are contained, the following two cases are included. One is a case where no carbon atom is contained at all. The other is a case where only a slight amount of carbon atoms such as less than 1 atomic % are contained.

Characteristics of the carbon-containing silicon nitride oxide film are described in greater detail below.

At first, HF resistance of the carbon-containing silicon nitride oxide film is described.

Herein, in the method as shown in FIG. 1, the film formation conditions, more specifically, the BTBAS flow rate/oxygen flow rate ratios are changed in the range of about 1/4 to about 30 to form various films on the silicon substrate. Then, these films are studied on an etching rate in the etching by an HF solution (having a concentration of about 0.5%). When forming each film, however, the conditions other than the BTBAS flow rate/oxygen flow rate ratio are set similarly. More specifically, the pressure within the film formation room is set to about 10 Pa, the film formation temperature is set to about 530° C. and the film thickness is set to about 90 nm. In order to match with thermal histories in the formation of transistors, the ion implantation is not performed and the RTA is performed at about 1000° C. for about 10 seconds. Then, each film is studied on the HF etching rate.

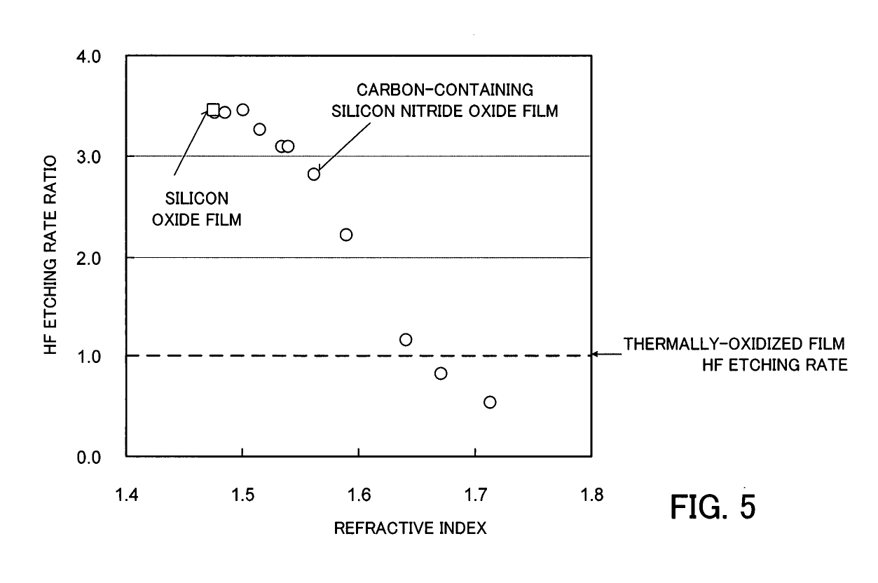

FIG. 5 shows a relation between a refractive index and the HF etching rate.

In FIG. 5, the horizontal axis shows a refractive index of each film, and the vertical axis shows an HF etching rate ratio of each film. As described above, during the film formation, as the BTBAS flow rate/oxygen flow rate ratio more decreases, the silicon oxide film is more readily formed. On the contrary, as the BTBAS flow rate/oxygen flow rate ratio more increases, the carbon-containing silicon nitride oxide film is more readily formed. It is known that the refractive index of the film shows a good corresponding relation with the nitrogen atom concentration in the film. In FIG. 5, as a film is formed under the condition where the BTBAS flow rate/oxygen flow rate ratio is smaller, the nitrogen atom concentration in the film more decreases and as a result, the refractive index more decreases. On the contrary, as a film is formed under the condition where the BTBAS flow rate/oxygen flow rate ratio is larger, the nitrogen atom concentration in the film more increases and as a result, the refractive index more increases. Furthermore, in FIG. 5, the HF etching rate of each formed film is evaluated as follows. Assuming that the etching rate at the time when a thermally-oxidized film formed on the silicon substrate is etched using the same HF solution is 1.0, the HF etching rate of each film is evaluated by a ratio (HF etching rate ratio) to the HF etching rate of the thermally-oxidized film.

From FIG. 5, the following facts are confirmed. When a silicon oxide film having a refractive index of about 1.48 is formed under conditions where the BTBAS flow rate/oxygen flow rate ratio is small, the HF etching of the silicon oxide film proceeds three or more times faster than that of the thermally-oxidized film. Furthermore, as the BTBAS flow rate/oxygen flow rate ratio more increases, more specifically, as the nitrogen atom concentration in the film more increases so as to increase the refractive index, the HF etching rate shows a tendency to decrease. When forming the carbon-containing silicon nitride oxide film having such a nitrogen atom concentration that the refractive index exceeds 1.65, the HF etching rate of the formed film is less than that of the thermally-oxidized film.

As described above, when the film contains an appropriate amount of nitrogen atoms, the HF resistance of the film is improved as compared with that of a film containing no nitrogen atom. When forming a sidewall using such the carbon-containing silicon nitride oxide film, recession of the sidewall can be suppressed also in the case of performing the HF treatment prior to the silicification. In addition, since the carbon-containing silicon nitride oxide film is formed under low temperature conditions of about 530° C., unnecessary impurity diffusion is suppressed, so that reduction in transistor characteristics can be prevented.

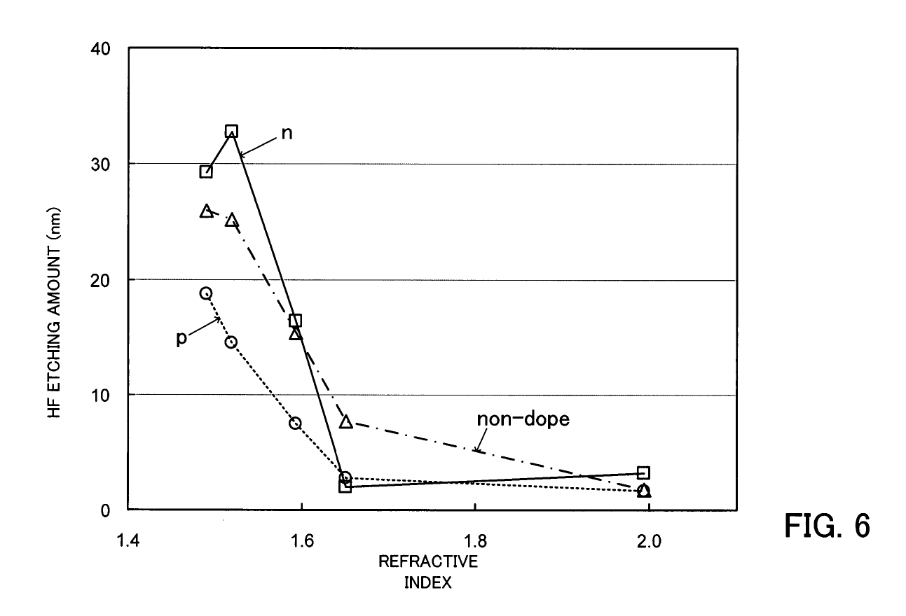

FIG. 6 shows a relation between a refractive index and an etching amount.

FIG. 6 shows measurement results of the HF etching amount in each film obtained by the following procedures. At first, starting materials and the composition thereof are changed to form various films. For the films, ion implantation of n type impurities (phosphorus, acceleration energy: about 10 keV, dose amount: about 1×10¹⁶ cm⁻²) or ion implantation of p type impurities (boron, acceleration energy: about 3 keV, dose amount: about 5×10¹⁵ cm⁻²) is performed and then, the RTA is performed at about 1000° C. for 10 seconds. Thereafter, the resulting films are etched using an HF solution (having a concentration of about. 0.5%) for a given length of time. Herein, these films are exposed to the HF solution as much as the time the thermally-oxidized film takes to be etched to a thickness of 6 nm.

In FIG. 6, the horizontal axis shows the refractive index of each film, and the vertical axis shows the HF etching amount (nm) of each film. The solid line shows a relation between the refractive index and the HF etching amount at the time when the ion implantation of phosphorus is performed (n in the figure). The broken line shows a relation between the refractive index and the HF etching amount at the time when the ion implantation of boron is performed (p in the figure). For the comparison, FIG. 6 simultaneously shows, using the dashed line, a relation between the refractive index and the HF etching amount at the time when the ion implantation of impurities is not performed and only the RTA is performed (non-dope in the figure).

During the formation of transistors, when the ion implantation for forming a source/drain region within the silicon substrate is performed using a sidewall as a mask, a certain degree of impurities are introduced also into the sidewall. Therefore, when studying the HF etching amount in the film after completion of the ion implantation, an effect of impurities introduced into the sidewall on the HF etching rate can be found out.

From FIG. 6, the following facts are found. At first, the silicon oxide film having a refractive index of about 1.48 is studied, which is formed under the conditions of the BTBAS flow rate/oxygen flow rate ratio of about 1/4, the pressure within the film formation room of about 10 Pa, and the film formation temperature of about 530° C. As a result, it is found that the film has a relatively large HF etching amount irrespective of implementation of the ion implantation. Further, when comparing the silicon oxide film subjected to the ion implantation of boron (p type) to the silicon oxide film subjected to the ion implantation of phosphorus (n type), a difference of about 10 nm is caused in the HF etching amount between both the films. More specifically, when forming the sidewall using the thus formed silicon oxide film, the following disadvantages are brought. After completion of the HF etching (after completion of the HF treatment), not only recession of the sidewall is caused but also the recession amount of the sidewall, in other words, a thickness of the sidewall remaining on the side wall of the gate electrode varies between a p-type transistor and an n-type transistor.

Next, the silicon nitride film having a refractive index of about 2.0 is studied, which is formed under the conditions of the BTBAS flow rate/ammonia flow rate ratio of about 1/4, the pressure within the film formation room of about 10 Pa, and the film formation temperature of about 600° C., using ammonia in place of oxygen in the starting materials. In this case, when comparing the silicon nitride film subjected to the ion implantation of boron (p type) to the silicon nitride film subjected to the ion implantation of phosphorus (n type), the following advantages are brought. In any film (both of p type and n type), the etching is preferably suppressed such that the HF etching amount is 5 nm or less. Furthermore, a difference in the etching amount between both the films is scarcely found. However, when thus forming the silicon nitride film, higher temperature conditions are normally required than when forming the silicon oxide film. Therefore, there is a higher possibility that during the film formation, unnecessary impurity diffusion is caused.

Next, the carbon-containing silicon nitride oxide film is studied, which is formed to have a refractive index of about 1.65 by leaving nitrogen atoms in the film, under the conditions of the BTBAS flow rate/oxygen flow rate ratio of about 30, the pressure within the film formation room of about 10 Pa and the film formation temperature of about 530° C. In this case, when comparing the carbon-containing silicon nitride oxide film subjected to the ion implantation of boron (p type) to the carbon-containing silicon nitride oxide film subjected to the ion implantation of phosphorus (n type), the following advantages are brought in the same manner as in the silicon nitride film. In any film (both of p type and n type), the etching is preferably suppressed such that the HF etching amount is 5 nm or less. Furthermore, a difference in the etching amount between both the films is scarcely found. Further, the carbon-containing silicon nitride oxide film has the advantage that the film formation can be performed under low temperature conditions, in the same manner as in the silicon oxide film.

As described above, the carbon-containing silicon nitride oxide film that contains a proper amount of nitrogen atoms has such advantages that high HF resistance is ensured mainly due to the contribution of the nitrogen atoms, film formation under low temperature conditions is allowed, and a difference (in the shape and characteristics) between the p-type transistor and the n-type transistor is prevented from occurring. Accordingly, the carbon-containing silicon nitride oxide film is suitable for construction materials for the sidewall.

Next, a dielectric constant of the carbon-containing silicon nitride oxide film is described.

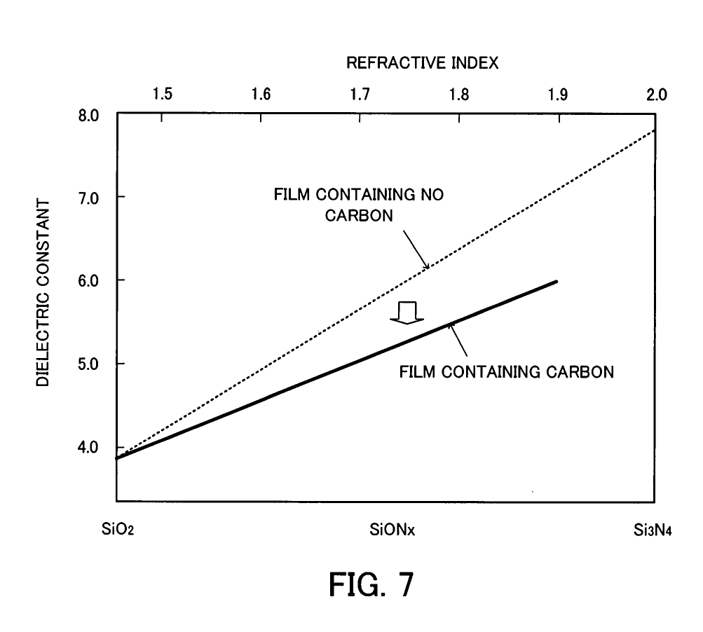

FIG. 7 shows a relation between a refractive index and dielectric constant of the silicon nitride oxide film.

In FIG. 7, the horizontal axis shows a composition and refractive index of the film, and the vertical axis shows a dielectric constant of the film. Further, the broken line shows a relation between the refractive index and dielectric constant of a film containing no carbon. The solid line shows a relation between the refractive index and dielectric constant of a film containing carbon.

From FIG. 7, the following facts are found. Irrespective of whether carbon is contained in the film, as the nitrogen atom concentration in the film more increases, the refractive index more increases and as a result, the dielectric constant increases with the increase in the refractive index. In the case of the carbon-containing silicon nitride oxide film formed by the above-described method, when the carbon atom concentration increases, the nitrogen atom concentration also increases in terms of the film formation mechanism. Therefore, in FIG. 7, as the film has a higher nitrogen atom concentration and a larger refractive index, it has a higher carbon atom concentration.

It should be herein noted that even if the films have the same refractive index, that is, the same level of nitrogen atom concentration, a film (indicated by the solid line) containing carbon atoms has a smaller dielectric constant as compared with a film (indicated by the broken line) containing no carbon atom. Therefore, in the case of forming the sidewall using the carbon-containing silicon nitride oxide film, the fringe capacitance can be reduced as compared with the case of forming it using the film containing no carbon atom. Accordingly, by the synergy effect of reduction in the fringe capacitance and the film formation under low temperature conditions, improvement of the transistor characteristics can be realized.

Next, etching selectivity of the carbon-containing silicon nitride oxide film is described.

Recently, an SRAM (Static Random Access Memory) using a shared contact technique for connecting a gate electrode and an impurity region within a silicon substrate by one contact is being proposed.

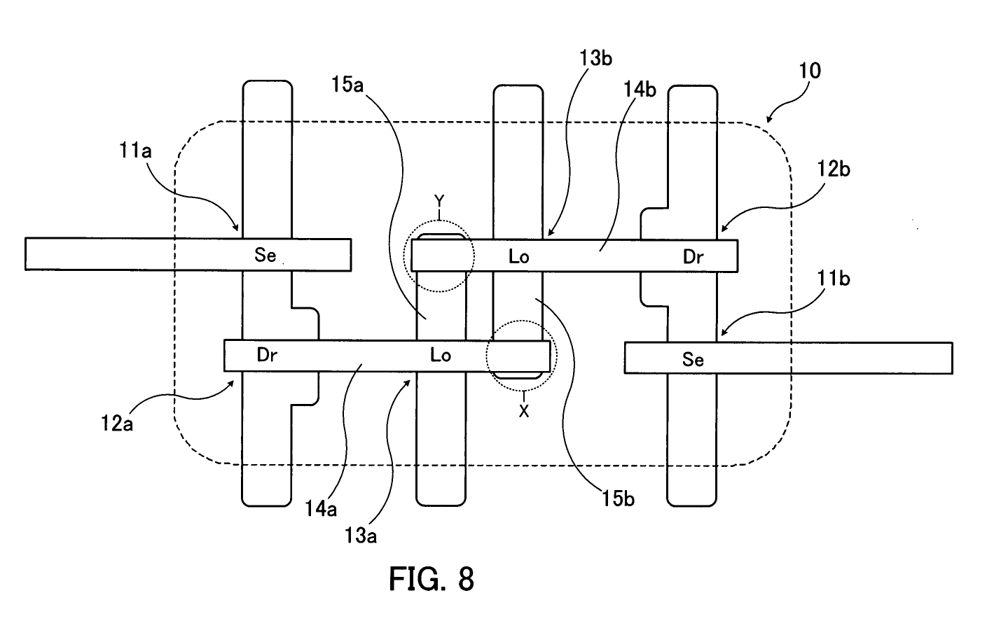

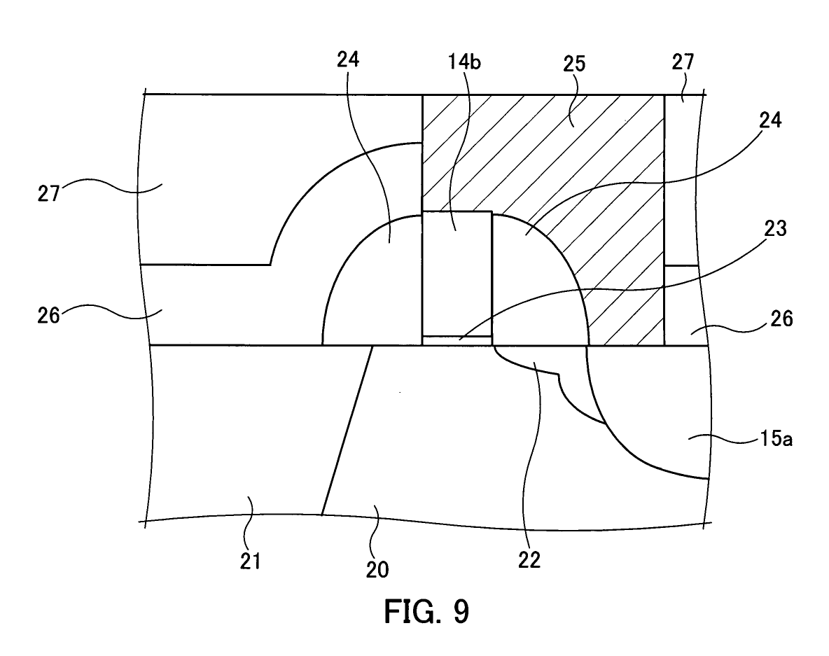

FIG. 8 is an outline schematic view of a transistor arrangement within an SRAM memory cell. FIG. 9 is a schematic cross-sectional view of a shared contact structure.

The SRAM memory cell 10 shown in FIG. 8 is configured by a total of six transistors of respective two select transistors (Se) 11a and 11b, driver transistors (Dr) 12a and 12b for writing and reading data, and load transistors (Lo) 13a and 13b. In the memory cell 10, a gate electrode 14a of one load transistor 13a is connected to a source/drain region 15b of another load transistor 13b (a connection part X). Further, a gate electrode 14b of the load transistor 13b is connected to a source/drain region 15a of the load transistor 13a (a connection part Y). When the connection parts X and Y are configured to have the shared contact structure, reduction in a cell area can be realized.

For example, the connection part Y can be configured to have the shared contact structure as shown in FIG. 9. As shown in FIG. 9, element isolation is appropriately performed within a silicon substrate 20 by STI 21. Further, an impurity region 22 containing a pocket region and an extension region, and a deep impurity region serving as the source/drain region 15a are formed within the silicon substrate 20. On the other hand, the gate electrode 14b is formed on the silicon substrate 20 through a gate insulating film 23, and the sidewall 24 is formed on the side wall of the gate electrode. The impurity region 22 is formed immediately below one sidewall 24. Further, the source/drain region 15a and the gate electrode 14b are directly connected by a contact metal 25. In the other regions on the silicon substrate 20, a silicon nitride film 26 is formed and thereon, a silicon oxide film 27 serving as an inter-layer insulating film is formed.

The shared contact structure as described above is formed as follows. At first, the gate insulating film 23 and the gate electrode 14b are formed on the silicon substrate 20. Using a publicly known method, ion implantation for the impurity region 22 and formation of the sidewall 24 are then performed appropriately. Thereafter, ion implantation for the source/drain region 15a is performed using the sidewall 24 as a mask and then, the silicon nitride film 26 and the silicon oxide film 27 are formed on the whole surface of the silicon substrate 20. Further, the silicon oxide film 27 and silicon nitride film 26 in a region where the contact metal 25 is to be formed are sequentially removed by dry etching and then, the region is filled with the contact metal 25.

Herein, assume that the sidewall 24 is formed by the silicon nitride film. In the sequential etching of the silicon oxide film 27 and the silicon nitride film 26 as a lower layer of the silicon oxide film 27, it is very difficult to discriminate a boundary between the silicon nitride film 26 and the sidewall 24, that is, a stopping place of the etching. As a result, the sidewall 24 is excessively etched, which readily leads to recession of the sidewall 24 toward the gate electrode 14b side.

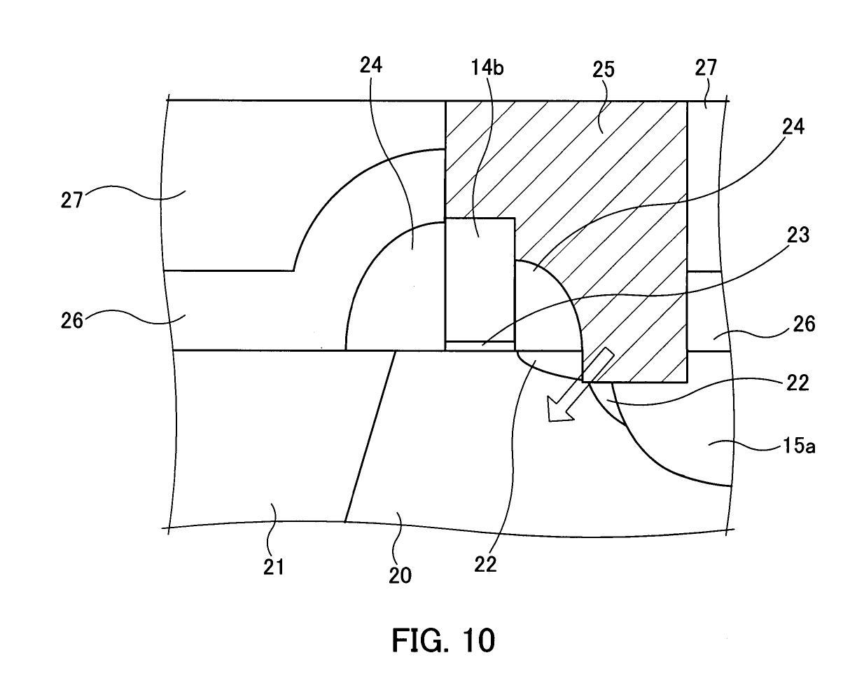

Further, assume that the sidewall 24 is formed by the silicon oxide film. In the etching of the silicon nitride film 26, it is possible to discriminate the stopping place of the etching. However, in this case, another problem as shown in the following FIG. 10 may occur in some cases.

FIG. 10 illustrates problems which may occur in the shared contact structure. In FIG. 10, the same elements as those in FIG. 9 are indicated by the same reference numerals as in FIG. 9 and their descriptions are omitted.

When forming the shared contact structure, or securing the connection, the silicon nitride film 26 is generally etched to a level where a surface layer of the source/drain region 15a on the silicon substrate 20 surface is slightly shaved. In this occasion, when the etching is excessively performed for some reason, the following problems may occur. As shown in FIG. 10, the sidewall 24 formed by a silicon oxide film recedes toward the gate electrode 14b side and as a result, the impurity region 22 as well as the surface layer of the source/drain region 15a is shaved. When the etching further proceeds to a level where the impurity region 22 is penetrated so that the silicon substrate 20 inside may be exposed, a large junction leakage (indicated by an arrow in the figure) is thereafter caused by the contact between the contact metal 25 and the silicon substrate 20 at the time of forming the contact metal 25.

Also in the case of thus forming the shared contact structure, an important subject is to suppress recession of the sidewall 24 due to the etching. Accordingly, when forming the sidewall 24 in the shared contact structure using the carbon-containing silicon nitride oxide film, the following advantages are obtained.

The first advantage is as follows. In the etching of the silicon nitride film 26, the stopping position of the etching can be readily discriminated between two different films of the silicon nitride film 26 and the carbon-containing silicon nitride oxide film. As a result, excessive etching of the sidewall 24 is prevented, so that recession of the sidewall 24 can be suppressed.

The second advantage is as follows. In the etching to the surface layer of the source/drain region 15a, since the carbon-containing silicon nitride oxide film contains carbon atoms, etching resistance is improved and the etching selectivity is secured, so that the recession of the sidewall 24 can be suppressed. As a result, during the etching, the impurity region 22 is protected by the sidewall 24, so that occurrence of the leakage can be prevented.

Also in view of the above-described advantages, when forming a high-performance transistor, the carbon-containing silicon nitride oxide film is suitably used for construction materials for the sidewall mainly due to the contribution of the carbon atoms. In this case, when the carbon content of the carbon-containing silicon nitride oxide film is from about 3 to about 20 atomic %, preferably from about 5 to about 15 atomic %, appropriate etching resistance as well as the reduction effect of the dielectric constant can be obtained. When the carbon content is less than about 3 atomic % or more than about 20 atomic %, the effect of containing carbon is not obtained, or the effect thereof is reduced even if it is obtained.

Next, a film formation property of the carbon-containing silicon nitride oxide film is described.

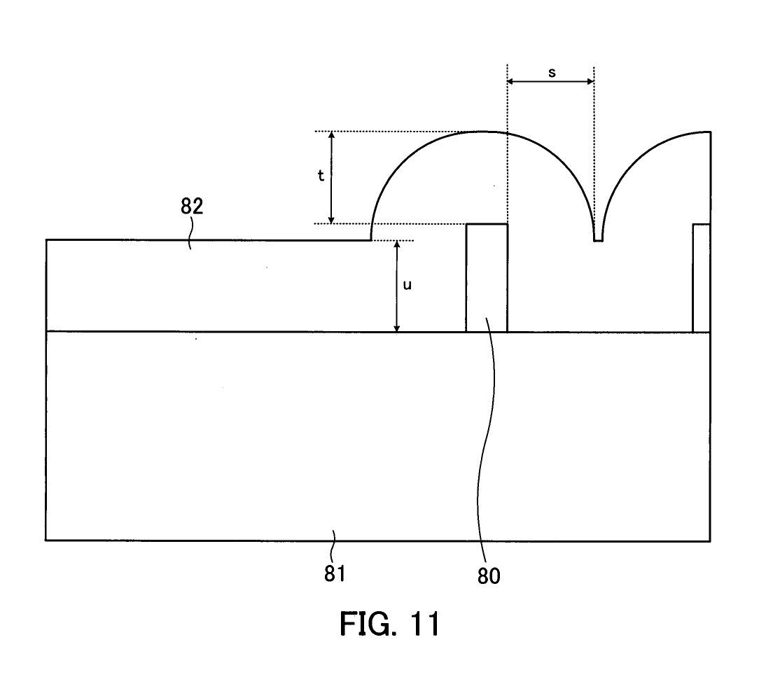

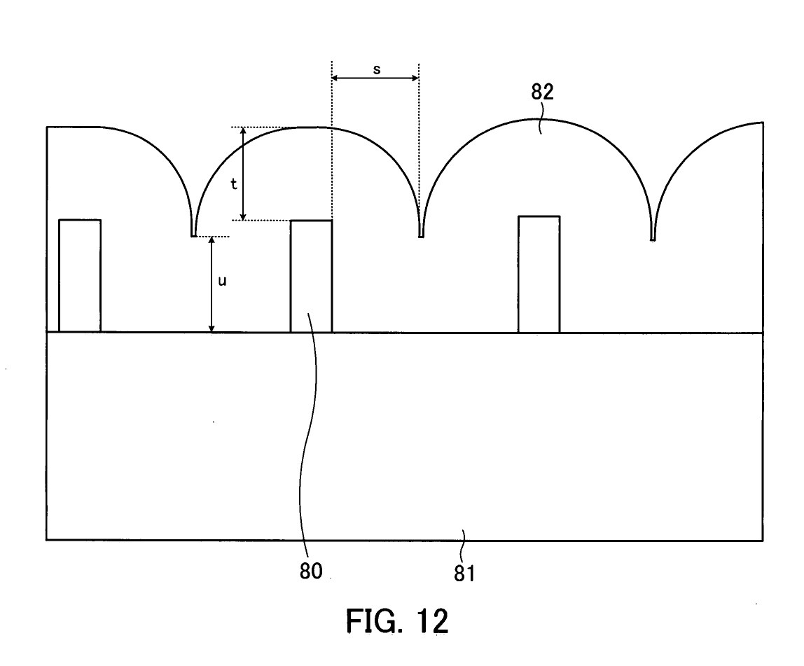

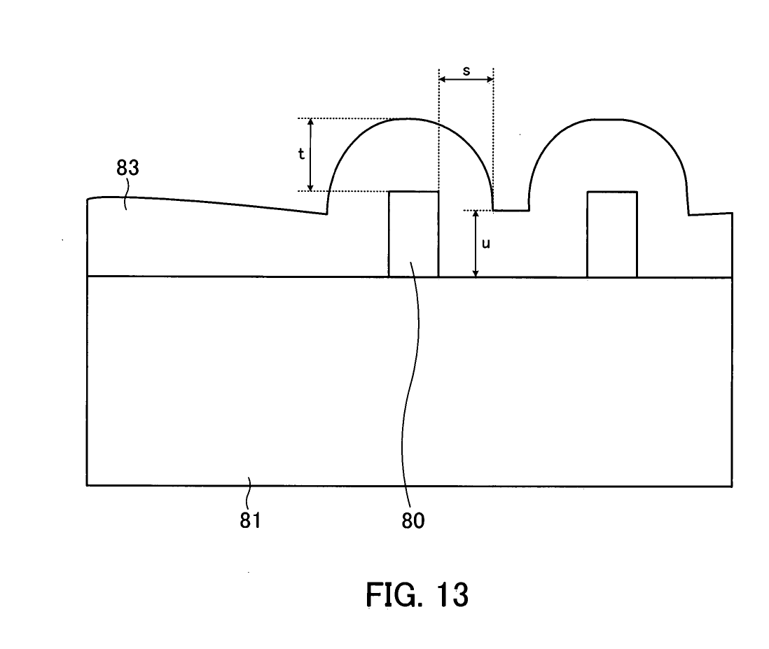

FIG. 11 is a schematic cross-sectional view of a pattern end in forming a sidewall using the carbon-containing silicon nitride oxide film. FIG. 12 is a schematic cross-sectional view of a pattern central part in forming a sidewall using the carbon-containing silicon nitride oxide film. FIG. 13 is a schematic cross-sectional view of a pattern end in forming a sidewall using the silicon oxide film.

Herein, the film formation property is evaluated using Side coverage X and Density dependence Y. Assume that a width of the gate electrode 80 side wall is s, a film thickness on the gate electrode 80 is t and a film thickness on the silicon substrate 81 of the gate electrode 80 side wall end is u at the time when the carbon-containing silicon nitride oxide film 82 or the silicon oxide film 83 is formed on the whole surface of the silicon substrate 81 having formed thereon the gate electrode 80. Based on the assumption, the Side coverage X and the Density dependence Y are determined by using the following formulae (1) and (2).
X=s/t×100 (1)
Y=u/t×100 (2)

Using, for example, a pattern obtained after forming the gate electrode 80 at a pitch of 0.22 μm, the film formation property is evaluated in the following two cases. In the case of forming the carbon-containing silicon nitride oxide film that covers the pattern (FIGS. 11 and 12), the following results are obtained. The Side coverage X at the pattern end is about 99% and that at the pattern central part is about 97%. Further, the Density dependence Y in the same pattern is about 99% at the pattern end and is about 97% at the pattern central part. On the other hand, in the case of forming the silicon oxide film that covers the pattern (FIG. 13), the following results are obtained. A part having an uneven film thickness is formed. Further, the Side coverage X at the pattern end is about 84% and that at the pattern central part is about 73%.

From the above results, the following facts are found. When the carbon-containing silicon nitride oxide film is used for the formation of the sidewall, the width s of the gate electrode 80 side wall at the time of forming the film can be uniformly and sufficiently secured irrespective of the end and central part of the pattern. On the other hand, when the silicon oxide film is used for the formation of the sidewall, the width s of the gate electrode 80 side wall at the time of forming the film cannot be secured as compared with the case where the carbon-containing silicon nitride oxide film is used. As the pattern is made denser, the tendency becomes more remarkable.

As described above, the carbon-containing silicon nitride oxide film has good step coverage as compared with the silicon oxide film and therefore, is suitable for construction materials for the sidewall, in particular, for the sidewall of the miniaturized high-performance transistor.

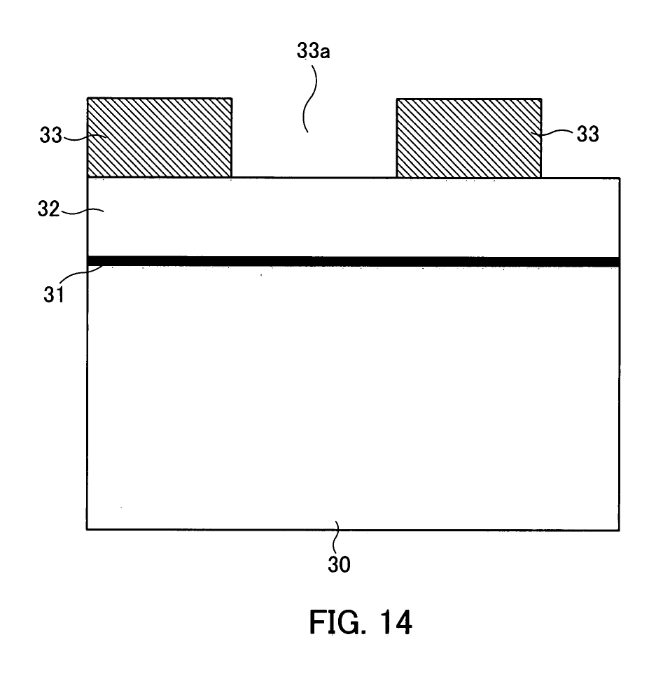

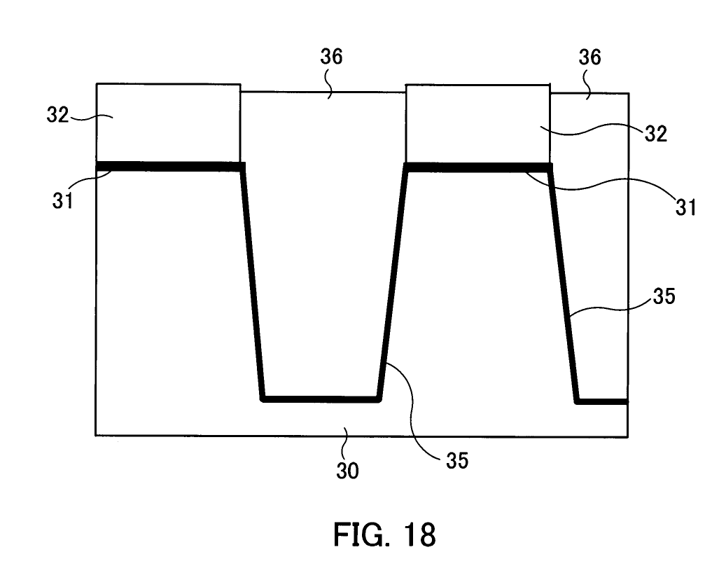

A method for manufacturing a semiconductor device using the carbon-containing silicon nitride oxide film is described below. Herein, using as an example a CMOS (Complementary Metal Oxide Semiconductor) forming step, the manufacturing method is sequentially described with reference to FIGS. 14 to 32.

FIG. 14 is a schematic cross-sectional view of an essential part in a forming step of a resist pattern for a trench.

The manufacture of the semiconductor device using the carbon-containing silicon nitride oxide film is performed as follows. At first, a silicon oxide film 31 is formed, for example, to a film thickness of about 10 nm on the surface of a silicon substrate 30 by the thermal oxidation method. Next, on the silicon oxide film 31, a silicon nitride film 32 for use in determining an element isolation region is formed, for example, to a film thickness of about 100 to 150 nm. Further, on the silicon nitride film 32, a resist pattern 33 for a trench having an opening 33a is formed in a region where the element isolation region is formed.

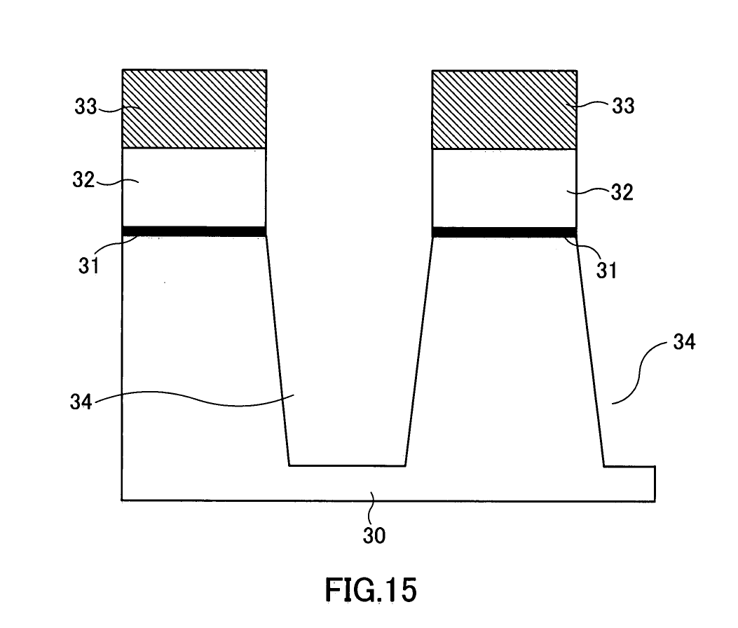

FIG. 15 is a schematic cross-sectional view of an essential part in a forming step of a trench.

After the formation of the resist pattern 33 for the trench, the silicon nitride film 32, the silicon oxide film 31 and the silicon substrate 30 are sequentially etched, by using the pattern 33 as a mask, to form a trench 34 within the silicon substrate 30. Thereafter, the resist pattern 33 for the trench is removed.

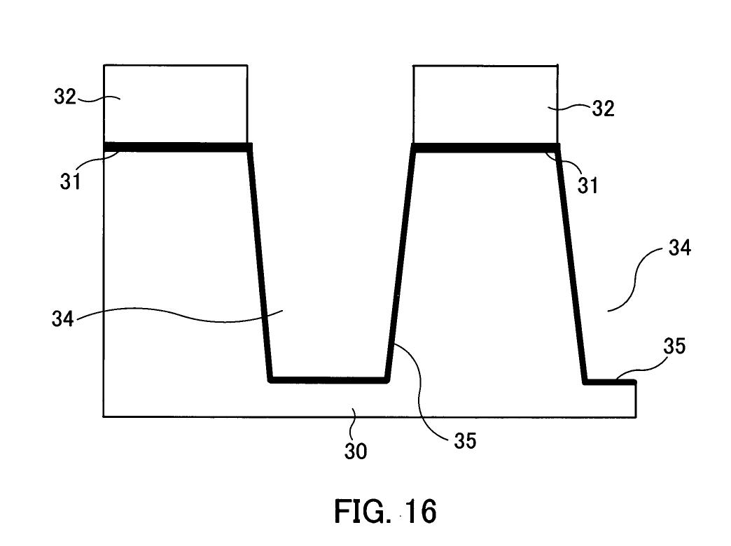

FIG. 16 is a schematic cross-sectional view of an essential part in an oxidizing step of a trench side wall.

After the formation of the trench 34, an exposed surface of the silicon substrate 30 is oxidized by the thermal oxidation method and thereby forming the silicon oxide film 35, for example, to a film thickness of about 10 nm on the side wall of the trench 34.

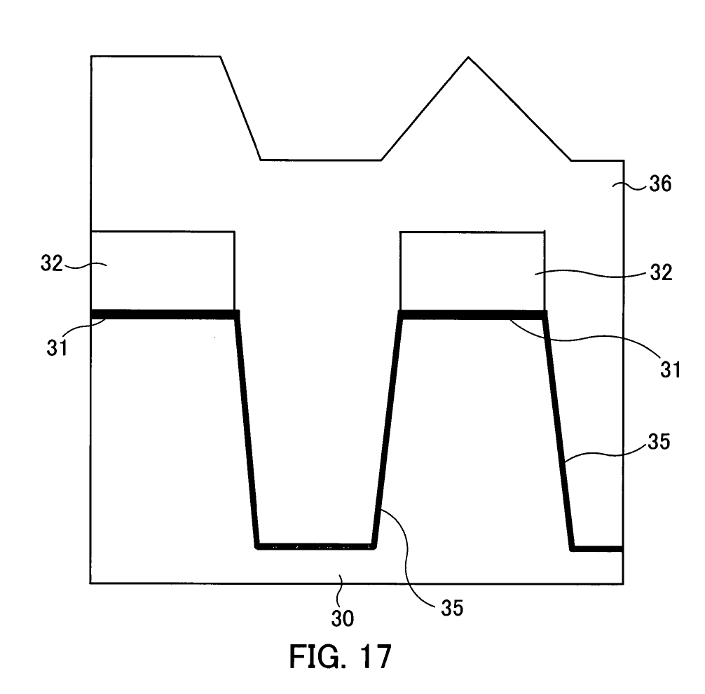

FIG. 17 is a schematic cross-sectional view of an essential part in a forming step of a buried oxide film. After forming the silicon oxide film 35 on the sidewall of the trench 34, a buried silicon oxide film 36 is formed, for example, to a film thickness of about 500 nm. The buried silicon oxide film 36 is formed, for example, by an HDP (High Density Plasma)-CVD method.

FIG. .18 is a schematic cross-sectional view of an essential part in planarizing and annealing steps.

After the silicon oxide film 36 is buried in the trench 34, at first, the silicon oxide film 36 is planarized by a CMP (Chemical Mechanical Polishing) method until the silicon nitride film 32 is exposed. Next, in order to densify the remaining silicon oxide film 36, annealing is performed, for example, at about 1000° C. in an atmosphere of a nitrogen gas.

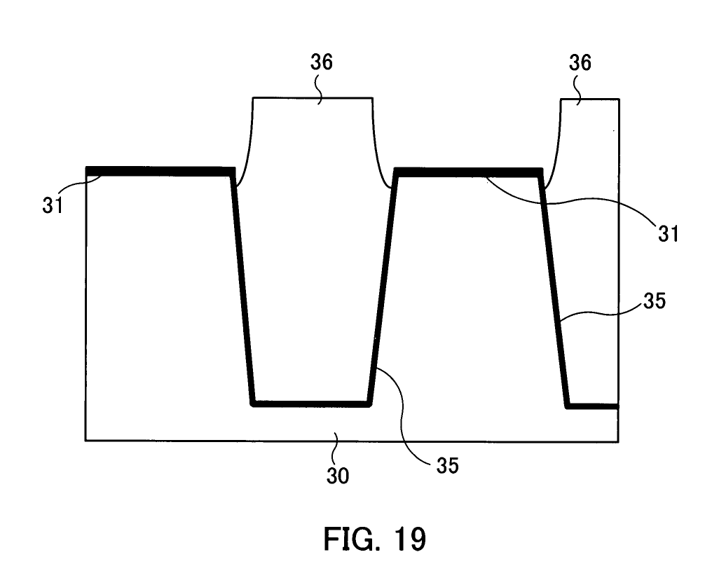

FIG. 19 is a schematic cross-sectional view of an essential part in a removing step of a silicon nitride film.

After completion of the annealing step, the silicon nitride film 32 is removed. The removal of the silicon nitride film 32 can be performed by etching, for example, using a hot phosphoric acid.

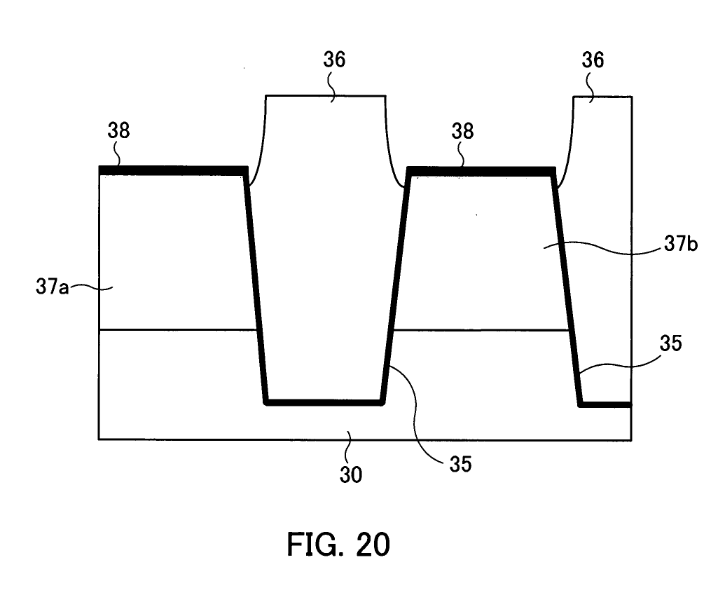

FIG. 20 is a schematic cross-sectional view of an essential part in a forming step of a well region and a gate insulating film.

After the removal of the silicon nitride film 32, sacrificial oxidation is performed. Then, impurities are ion-implanted into the silicon substrate 30, whereby well regions 37a and 37b are formed in regions for forming an n MOS transistor and a p MOS transistor, respectively. For example, on the region for forming the n MOS transistor, the well region 37a is formed by the implantation of boron ions under conditions that the acceleration energy is about 200 keV and the dose amount is about 3×10¹³ cm⁻².

Further, on the region for forming the p MOS transistor, the well region 37b is formed by the implantation of phosphorus ions under conditions that the acceleration energy is about 350 keV and the dose amount is about 3×10¹³ cm⁻². Thereafter, the HF treatment is performed to remove the sacrificial oxide film. Then, the cleaned surface of the silicon substrate 30 is oxidized by the thermal oxidation method to form thereon a gate insulating film 38. The gate insulating film 38 is formed, for example, to a film thickness of about 2 nm.

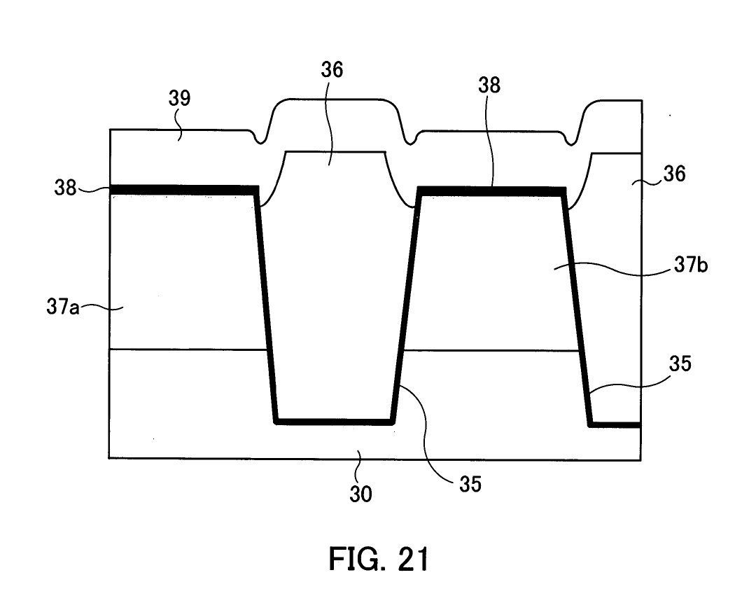

FIG. 21 is a schematic cross-sectional view of an essential part in a forming step of a polycrystalline silicon film.

After the formation of the gate insulating film 38, the polycrystalline silicon film 39 for the gate electrode is formed on the whole surface of the film 38. The polycrystalline silicon film 39 is formed, for example, to a film thickness of about 100 nm using an LP (Low Pressure)-CVD method, for example, at about 600° C.

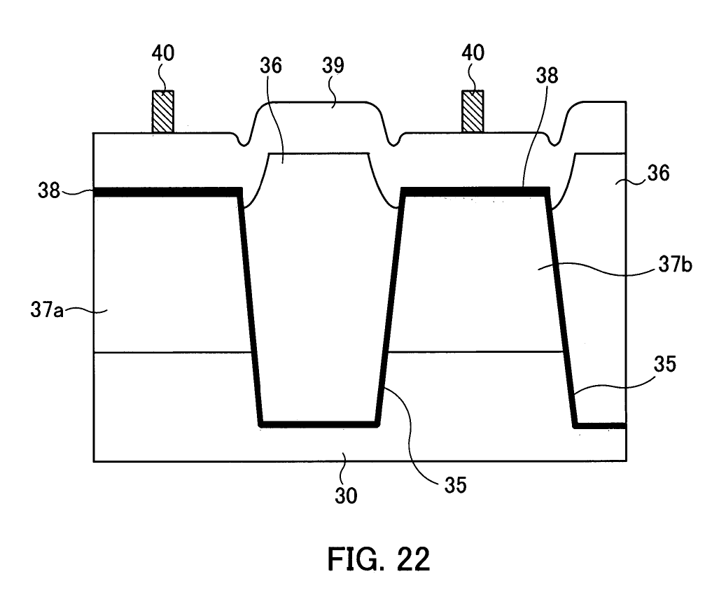

FIG. 22 is a schematic cross-sectional view of an essential part in a forming step of a resist pattern for a gate electrode.

After the formation of the polycrystalline silicon film 39, a resist pattern 40 for a gate electrode is formed, in which a resist is allowed to remain only in the region for forming the gate electrode.

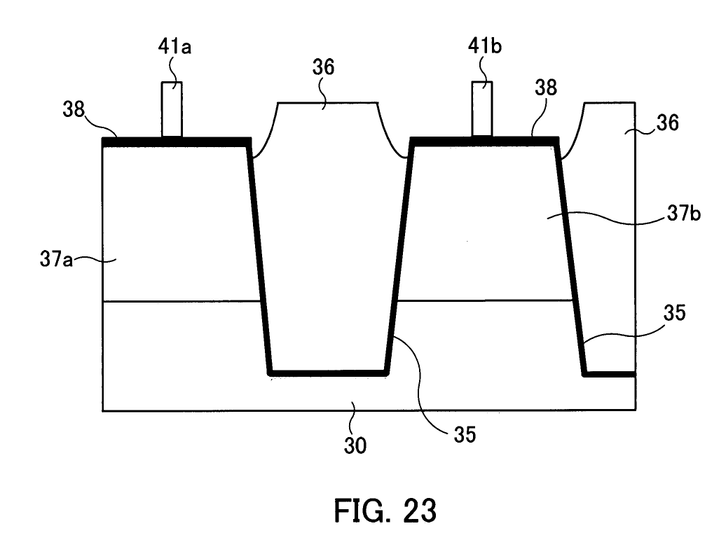

FIG. 23 is a schematic cross-sectional view of an essential part in a forming step of a gate electrode.

Using as a mask the resist pattern 40 for the gate electrode, anisotropic etching is performed to process the polycrystalline silicon film 39 and thereby, forming the gate electrodes 41a and 41b having a gate length of about 40 nm. Then, the resist pattern 40 for the gate electrode is removed.

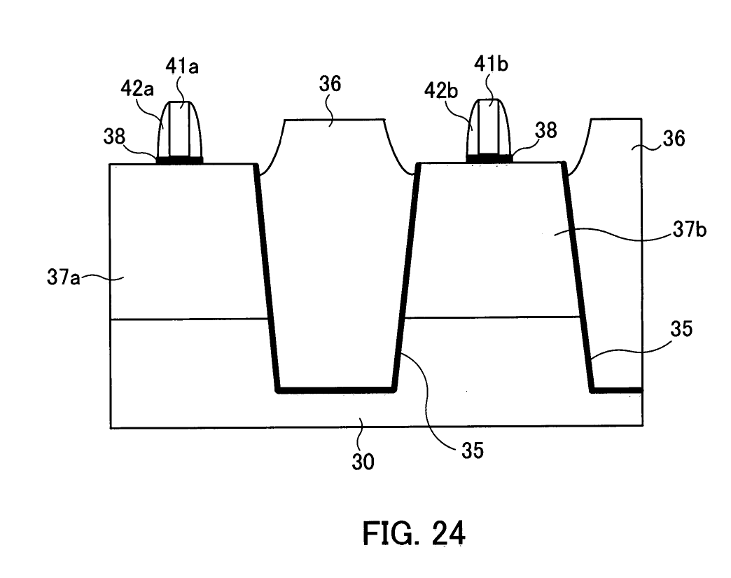

FIG. 24 is a schematic cross-sectional view of an essential part in a forming step of a first sidewall.

After the formation of the gate electrodes 41a and 41b, the silicon oxide film, the silicon nitride film or the carbon-containing silicon nitride oxide film is formed, for example, to a film thickness of about 10 nm on the whole surface, under publicly known film formation conditions or under the above-described low temperature film formation conditions. Then, the film is processed by the anisotropic etching and thereby, the first sidewalls 42a and 42b having a thickness of the lowermost part of about 5 to about 10 nm are formed on the side walls of the gate electrodes 41a and 41b.

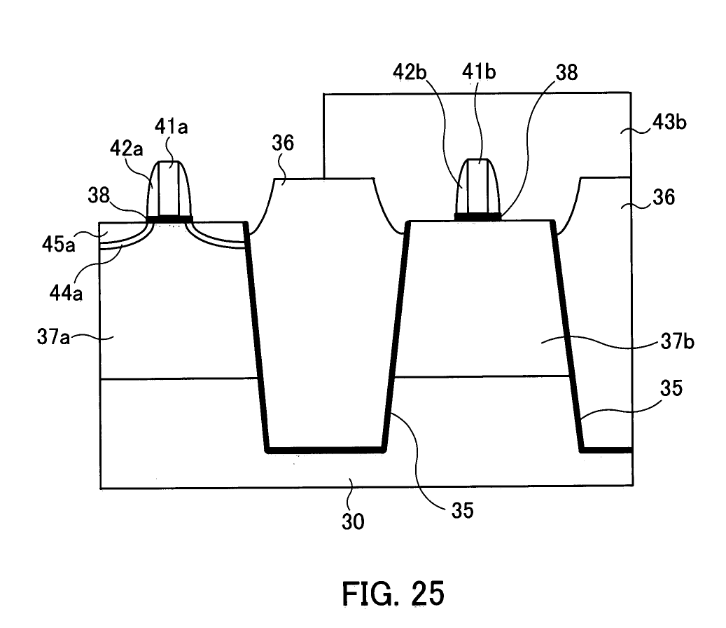

FIG. 25 is a schematic cross-sectional view of an essential part in a forming step of a shallow impurity region of the n MOS transistor.

After the formation of the first sidewalls 42a and 42b, a resist film 43b is formed on the region for forming the p MOS transistor. Using the gate electrode 41a and the first sidewall 42a as masks, for example, boron ions are first implanted into the silicon substrate 30 on the region for forming the n MOS transistor, under conditions that the acceleration energy is about 7 keV and the dose amount is about 4×10¹³ cm⁻². As a result, a pocket region 44a is formed within the silicon substrate 30 on both sides of the gate electrode 41a of the n MOS transistor. Incidentally, indium (In⁺) ions may be implanted herein in place of boron.

After the formation of the pocket region 44a, for example, arsenic (As⁺) ions are implanted into the silicon substrate 30 under conditions that the acceleration energy is about 3 keV and the dose amount is about 1.5×10¹⁵ cm⁻². As a result, an extension region 45a is formed within the silicon substrate 30 on both sides of the gate electrode 41a of the n MOS transistor. Thereafter, the resist film 43b is removed.

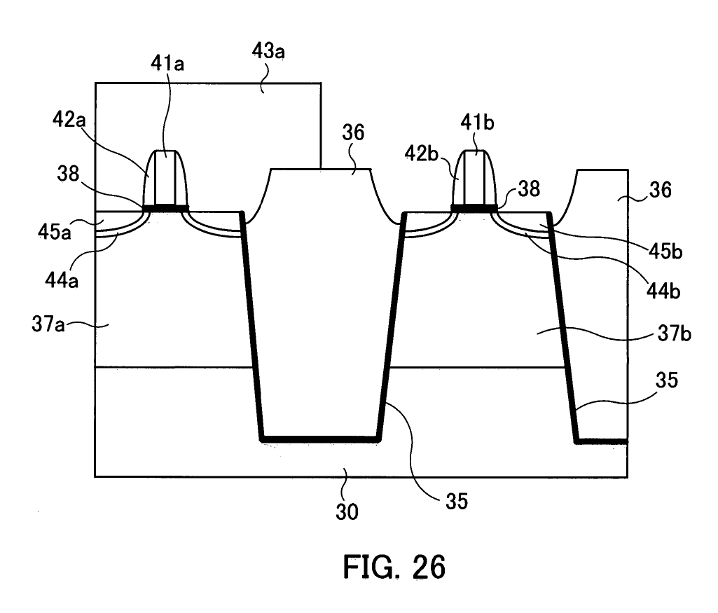

FIG. 26 is a schematic cross-sectional view of an essential part in a forming step of a shallow impurity region of the p MOS transistor.

In the same manner as in the step shown in FIG. 25, the resist film 43a is in turn formed on the region for forming the n MOS transistor. Using the gate electrode 41b and the first sidewall 42b as masks, for example, arsenic ions are first implanted into the silicon substrate 30 on the region for forming the p MOS transistor, under conditions that the acceleration energy is about 50 keV and the dose amount is about 2×10¹³ cm⁻². As a result, a pocket region 44b is formed within the silicon substrate 30 on both sides of the gate electrode 41b of the p MOS transistor. Incidentally, antimony ions (Sb⁺) may be implanted herein in place of arsenic ions.

After the formation of the pocket region 44b, for example, boron ions are implanted into the silicon substrate 30 under conditions that the acceleration energy is about 0.5 keV and the dose amount is about 1.5×10¹⁵ cm⁻². As a result, an extension region 45b is formed within the silicon substrate 30 on both sides of the gate electrode 41b of the p MOS transistor. Thereafter, the resist film 43a is removed.

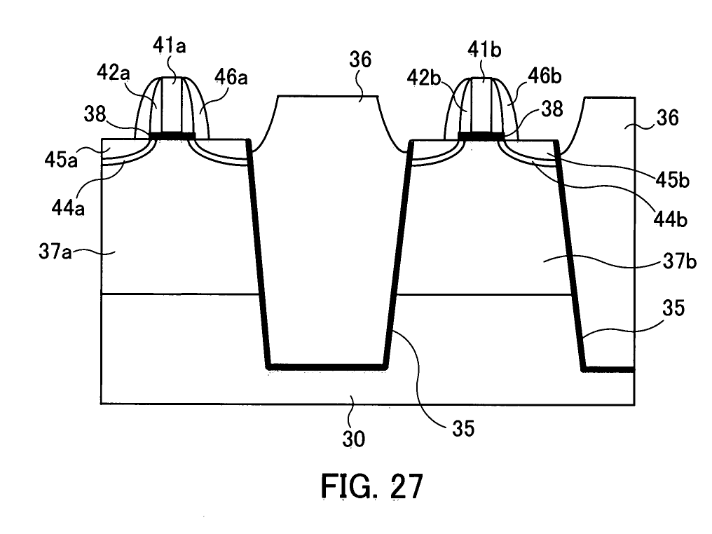

FIG. 27 is a schematic cross-sectional view of an essential part in a forming step of a second sidewall.

After the formation of the pocket regions 44a and 44b, and the extension regions 45a and 45b, in the same manner as in the formation of the first sidewalls 42a and 42b, the silicon oxide film, the silicon nitride film or the carbon-containing silicon nitride oxide film is formed, for example, to a film thickness of about 30 nm on the whole surface, under publicly known film formation conditions or under the above-described low temperature film formation conditions. Further, the film is processed by the anisotropic etching and thereby, second sidewalls 46a and 46b having a thickness of the lowermost part of about 20 to about 30 nm are formed outside the first sidewalls 42a and 42b on the gate electrodes 41a and 41b side walls.

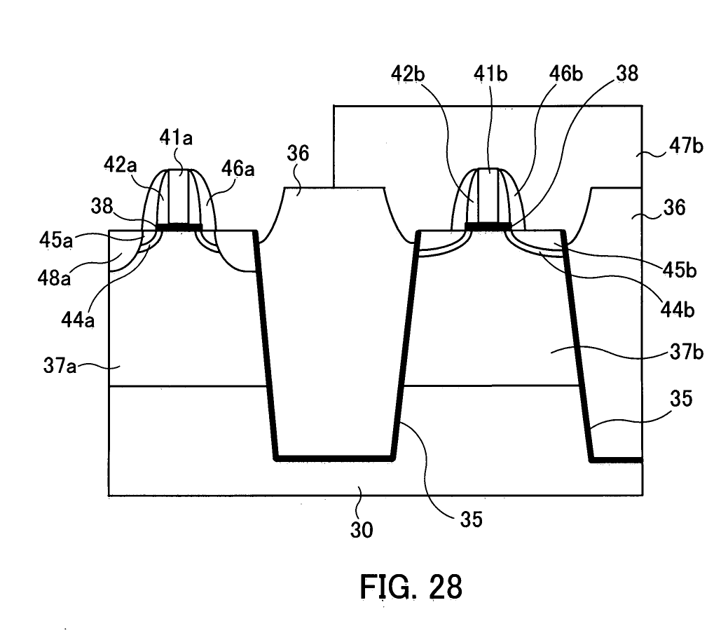

FIG. 28 is a schematic cross-sectional view of an essential part in a forming step of a first source/drain region of the n MOS transistor.

After the formation of the second sidewalls 46a and 46b, a resist film 47b is formed again on the region for forming the p MOS transistor. Using the gate electrode 41a and the first and second sidewalls 42a and 46a as masks, for example, arsenic ions are implanted into the silicon substrate 30 on the region for forming the n MOS transistor, under conditions that the acceleration energy is about 15 keV and the dose amount is about 1×10¹⁵ cm⁻². As a result, a relatively shallow first source/drain region 48a is formed within the silicon substrate 30 on both sides of the gate electrode 41a of the n MOS transistor. Thereafter, the resist film 47b is removed.

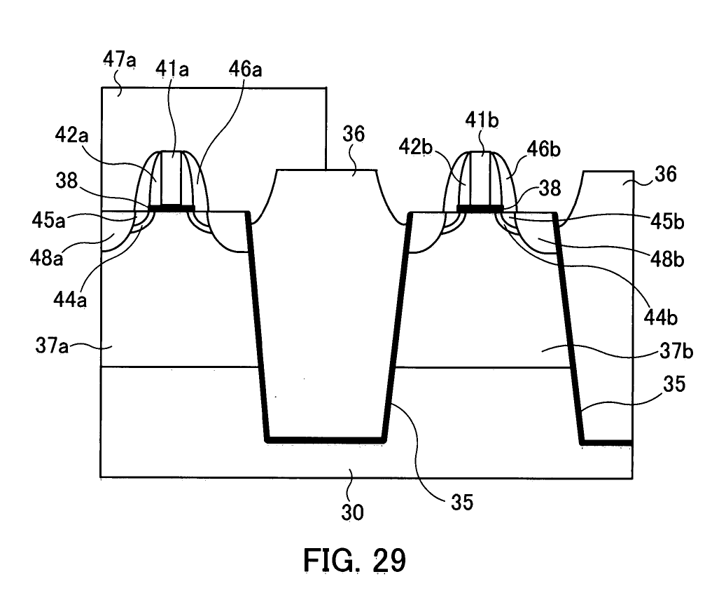

FIG. 29 is a schematic cross-sectional view of an essential part in a forming step of the first source/drain region of the p MOS transistor.

In the same manner as in the step shown in FIG. 28, a resist film 47a is in turn formed on the region for forming the n MOS transistor. Using the gate electrode 41b and the first and second sidewalls 42b and 46b as masks, for example, boron ions are implanted into the silicon substrate 30 on the region for forming the p MOS transistor, under conditions that the acceleration energy is about 1 keV and the dose amount is about 1×10 cm⁻². As a result, a relatively shallow first source/drain region 48b is formed within the silicon substrate 30 on both sides of the gate electrode 41b of the p MOS transistor. Thereafter, the resist film 47a is removed.

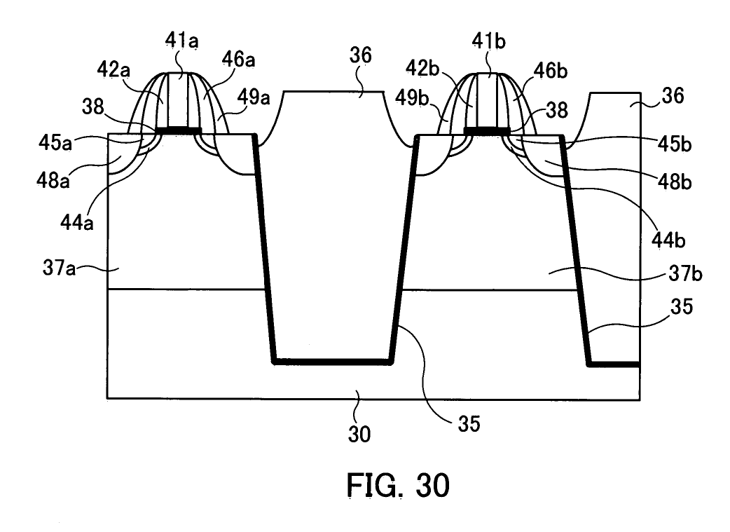

FIG. 30 is a schematic cross-sectional view of an essential part in a forming step of a third sidewall.

After the formation of the first source/drain regions 48a and 48b, the carbon-containing silicon nitride oxide film is formed, for example, to a film thickness of about 100 nm on the whole surface, under the above-described low temperature film formation conditions. Further, the film is processed by the anisotropic etching and thereby, third sidewalls 49a and 49b having a thickness of the lowermost part of about 30 to about 40 nm are formed outside the second sidewalls 46a and 46b. The first sidewalls 42a and 42b, or the second sidewalls 46a and 46b may be configured by any of the silicon oxide film, the silicon nitride film or the carbon-containing silicon nitride oxide film. However, the third sidewalls 49a and 49b are configured by the carbon-containing silicon nitride oxide film.

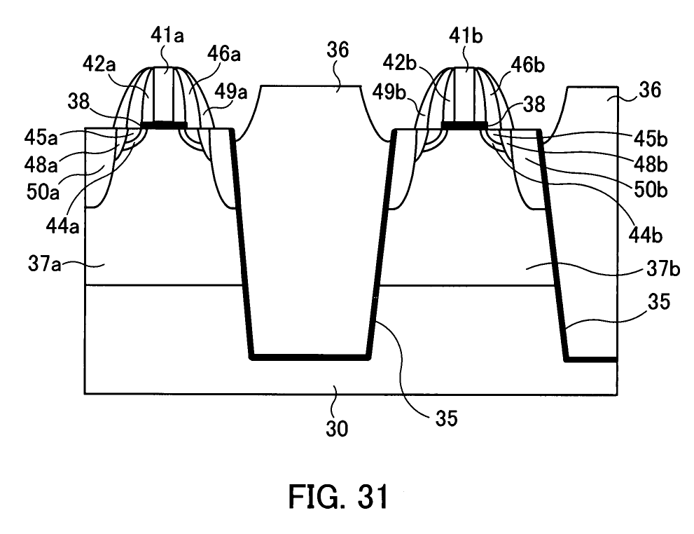

FIG. 31 is a schematic cross-sectional view of an essential part in a forming step of the second source/drain region.

After the formation of the third sidewalls 49a and 49b, a resist film (not shown) is formed on the region for forming the p MOS transistor. Using the gate electrode 41a and the first, second and third sidewalls 42a, 46a and 49a as masks, for example, phosphorus ions are implanted into the silicon substrate 30 on the region for forming the n MOS transistor, under conditions that the acceleration energy is about 10 keV and the dose amount is about 8×10¹⁵ cm⁻². As a result, a second source/drain region 50a is formed in the region deeper than the first source/drain region 48a within the silicon substrate 30 on both sides of the gate electrode 41a of the n MOS transistor. Thereafter, the resist film is removed.

In the same manner as in the step of forming the second source/drain region 50a, a resist film (not shown) is in turn formed on the region for forming the n MOS transistor. Using the gate electrode 41b and the first, second and third sidewalls 42b, 46b and 49b as masks, for example, boron ions are implanted into the silicon substrate 30 on the region for forming the p MOS transistor, under conditions that the acceleration energy is about 5 keV and the dose amount is about 4×10¹⁵ cm⁻². As a result, a second source/drain region 50b is formed in the region deeper than the first source/drain region 48b within the silicon substrate 30 on both sides of the gate electrode 41b of the p MOS transistor. Thereafter, the resist film is removed.

After the formation of the second source/drain regions 50a and 50b, RTA is performed, for example, at about 1000° C. for about 10 seconds to activate impurities ion-implanted into the silicon substrate 30.

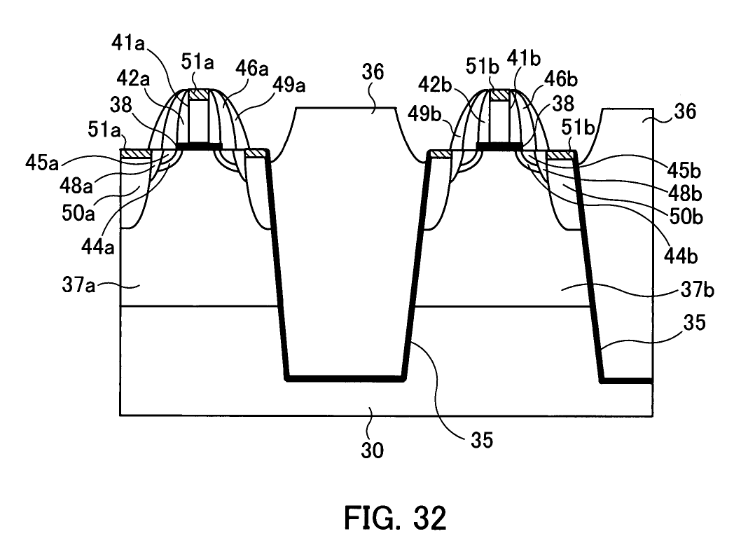

FIG. 32 is a schematic cross-sectional view of an essential part in a silicification step.

After completion of the RTA, the HF treatment is performed prior to the silicification to remove a natural oxide film or etching residue. At this time, recession of the sidewall during the HF treatment is effectively suppressed. This is because among the sidewalls provided on the side walls of the gate electrodes 41a and 41b, at least the third sidewalls 49a and 49b formed on the outermost part are configured by the carbon-containing silicon nitride oxide film.

After completion of the HF treatment, cobalt is deposited to a film thickness of about 5 nm on the whole surface, for example, by the sputtering method and is subjected to a thermal treatment at about 400° C. As a result, cobalt silicide (CoSiₓ) layers 51a and 51b having a film thickness of about 15 nm are formed on surface layers of the silicon substrate 30 and the polycrystalline silicon film 39, which contact with cobalt, more specifically, on surface layers of the second source/drain regions 50a and 50b, and the gate electrodes 41a and 41b. Unreacted cobalt is thereafter removed by the HF treatment. Also at this time, the third sidewalls 49a and 49b configured by the carbon-containing silicon nitride oxide film effectively function.

Incidentally, the cobalt silicide layer is formed herein by depositing cobalt. Further, a nickel silicide (NiSiₓ) layer may be formed by depositing nickel (Ni) in place of cobalt.

Through the above-described steps, a fundamental structure of the CMOS is completed. In response to the shape of the semiconductor device, the formation of the inter-layer insulating film, the contact hole and the electrode is hereafter performed according to the conventionally known steps.

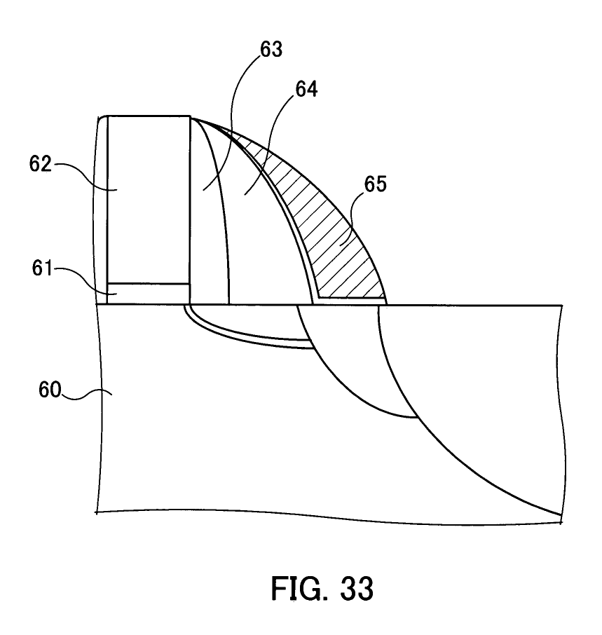

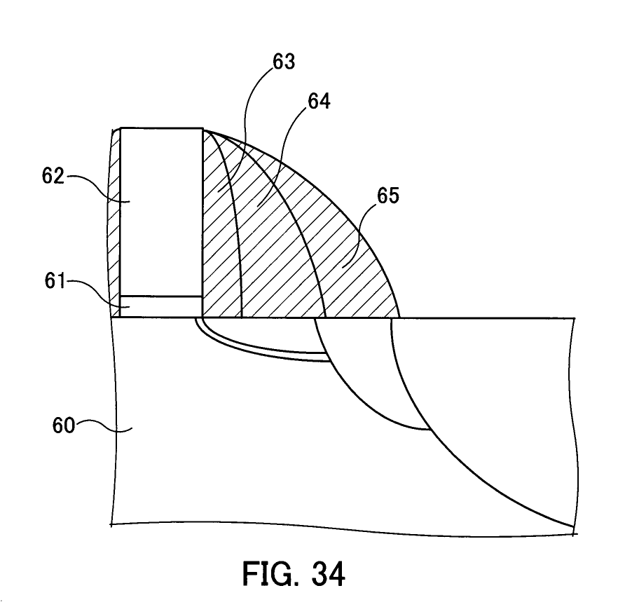

An example of the manufacturing method of the semiconductor device using the carbon-containing silicon nitride oxide film is described above. As described above, the carbon-containing silicon nitride oxide film is suitable for the sidewall of the semiconductor device. The film can also be used, for example, in the following shapes shown in FIGS. 33 and 34.

FIGS. 33 and 34 are schematic cross-sectional views of essential parts, which illustrate an application example of the carbon-containing silicon nitride oxide film.

When forming the sidewall having a structure as described above, the sidewall can be formed to have a configuration, for example, as shown in FIG. 33. More specifically, the first and second sidewalls 63 and 64 on the side wall of the gate electrode 62 formed on the silicon substrate 60 through the gate insulating film 61 are formed by the conventional silicon oxide film. Further, only the outermost third sidewall 65 is configured by the carbon-containing silicon nitride oxide film. Alternatively, as shown in FIG. 34, all of the first, second and third sidewalls 63, 64 and 65 may be configured by the carbon-containing silicon nitride oxide film. As described above, when at least an outermost portion exposed to the HF solution during the HF treatment is configured by the carbon-containing silicon nitride oxide film, the film formation can be performed under low temperature conditions. As a result, the following two effects can be obtained. That is, impurity diffusion during the formation of the sidewall can be suppressed and in addition, recession of the sidewall during the HF treatment can be suppressed.

As long as a portion exposed to the HF solution before the silicification is configured by the carbon-containing silicon nitride oxide film, the sidewall may have a structure containing only one layer of the carbon-containing silicon nitride oxide film or may have a double structure containing the carbon-containing silicon nitride oxide film, of course, in response to the shape (the configuration of impurity regions) of the transistor to be formed.

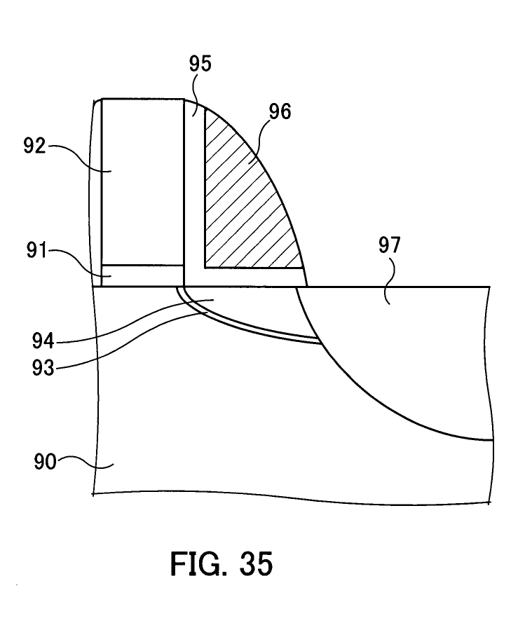

FIG. 35 is a schematic cross-sectional view of an essential part, which illustrates an application example of the carbon-containing silicon nitride oxide film to the sidewall having the double structure.

The transistor as shown in FIG. 35 is formed as follows. At first, the gate electrode 92 is formed on the silicon substrate 90 through the gate insulating film 91. Then, using the gate electrode 92 as a mask, ion implantation for forming the pocket region 93 and the extension region 94 is sequentially performed. Thereafter, two layers of insulating films are formed such that at least the upper layer side is configured by the carbon-containing silicon nitride oxide film. Then, the insulating films are etched back to form the first and second sidewalls 95 and 96. Further, using the first and second sidewalls 95 and 96 as masks, ion implantation for forming the source/drain region 97 is performed, followed by performing the RTA. When performing the silicification, the HF treatment is performed after completion of the ion implantation and the RTA. Then, a normal silicification layer forming step is performed.

When the sidewall is formed to have the double layer structure as described above, at least the second sidewall 96 is formed by the carbon-containing silicon nitride oxide film. When the carbon-containing silicon nitride oxide film is thus formed on the surface of the sidewall, the recession of the sidewall is suppressed even if the HF treatment is performed before the silicification.

Further, when the sidewall is formed to have this double structure, the first sidewall 95 formed on the sidewall of the gate electrode 92 may be formed by the carbon-containing silicon nitride oxide film or by the silicon oxide film. For example, when the first sidewall 95 is formed by the silicon oxide film and the second sidewall 96 is formed by the carbon-containing silicon nitride oxide film, both of the silicon oxide film and the carbon-containing silicon nitride oxide film can be formed at the same film formation temperature using BTBAS and oxygen as starting materials. Therefore, when the BTBAS flow rate/oxygen flow rate ratio during the film formation is adjusted, the two layers can be sequentially formed. Further, both of the two layers can be formed under low temperature conditions such as 530° C. Therefore, impurity diffusion during the formation of the sidewall can be suppressed. Of course, the same is equally true of forming the first sidewall 95 by the carbon-containing silicon nitride oxide film.

As described above, when the carbon-containing silicon nitride oxide film is applied to the sidewall having a double structure, the following advantages can be obtained. For example, as compared with a conventional case where the silicon nitride film is used for the outside sidewall, the sidewall can be more effectively formed with avoidance of unnecessary impurity diffusion and also, recession of the sidewall in the HF treatment can be suppressed.

Further, the carbon-containing silicon nitride oxide film can be effectively used in the HF treatment step before the salicidation step as well as in other steps where the HF resistance is required.

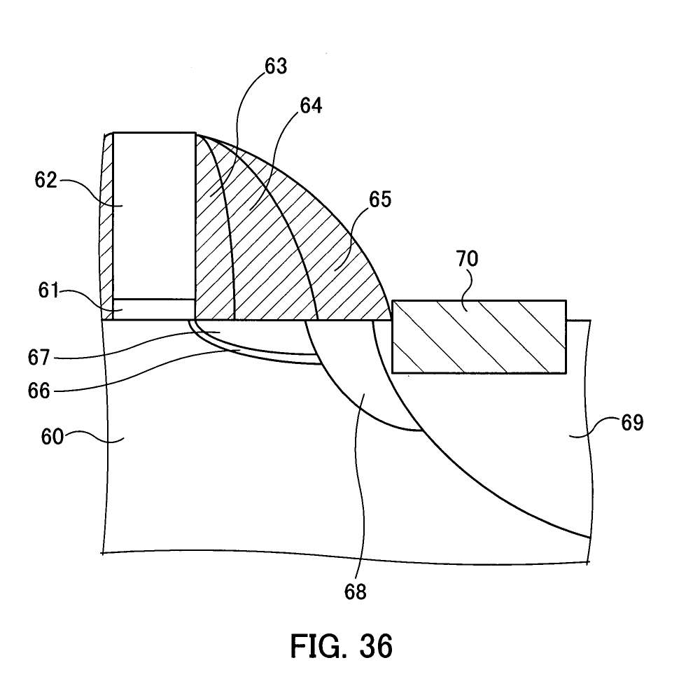

FIGS. 36 to 38 are schematic cross-sectional views of essential parts, which illustrate another application example of the carbon-containing silicon nitride oxide film. In FIGS. 36 to 38, the same elements as those in FIGS. 33 and 34 are indicated by the same reference numerals as in FIGS. 33 and 34 and their descriptions are omitted.

The transistor shown in FIG. 36 is formed as follows. At first, the gate insulation film 61, the gate electrode 62 and the first sidewall 63 are formed on the silicon substrate 60 and then, a pocket region 66 and an extension region 67 are formed. Further, the second sidewall 64, a shallow first source/drain region 68 and the third sidewall 65 are formed and then, a deep second source/drain region 69 is formed within the silicon substrate 60. Thereafter, a trench is formed within the second source/drain region 69 and therein, the silicon germanium layer 70 containing impurities is formed by epitaxial growth. When a compound semiconductor layer having a lattice constant different from that of the silicon substrate 60, such as the silicon germanium layer 70, is formed within the second source/drain region 69, distortion is caused in the channel region within the silicon substrate 60, so that speeding up of the transistor can be realized.

When forming this structure, the trench inside wall must be cleaned by the HF treatment before the epitaxial growth of the silicon germanium layer 70. In the HF treatment, when the outermost third sidewall 65 is configured, for example, by the silicon oxide film, the recession of the sidewall 65 cannot be avoided. Accordingly, when the carbon-containing silicon nitride oxide film is used for at least the third sidewall 65, the recession of the sidewall 65 is suppressed. Further, as shown in FIG. 36, when forming the sidewall using the carbon-containing silicon nitride oxide film, reduction in the fringe capacitance also is realized, as compared with the case of forming it using the silicon nitride film having the HF resistance. As a result, highly stable transistor characteristics can be obtained.

Also when the sidewall is formed to have the double structure as shown in FIG. 35, in the same manner as in the example shown in FIG. 36, speeding up of the transistor can be realized by the formation of the silicon germanium layer. More specifically, after the formation of the first and second sidewalls 95 and 96 and the source/drain region 97, a trench is formed within the source/drain region 97 and subjected to the HF treatment. Thereafter, the silicon germanium layer may be formed in the trench by the epitaxial growth.

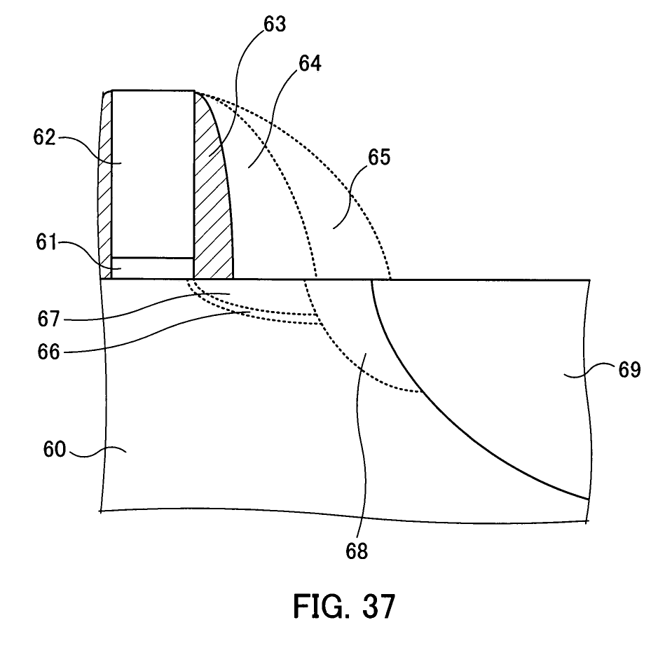

In the example shown in FIG. 37, the carbon-containing silicon nitride oxide film is formed on the part that is in contact with the side wall of the gate electrode 62. In the example, the first sidewall 63 is first formed by the carbon-containing silicon nitride oxide film. Then, sidewalls having shapes corresponding to those of the second and third sidewalls 64 and 65 are formed outside the first sidewall 63. The sidewalls formed outside the first sidewall 63 may have either the single layer structure or the double structure. Further, the sidewalls may be formed by a film other than the carbon-containing silicon nitride oxide film, for example, the silicon oxide film.

Using these sidewalls as masks, the deep second source/drain region 69 is first formed within the silicon substrate 60. Thereafter, the sidewalls formed outside the first sidewall 63 are removed by the HF treatment. Through the previous steps, the structure indicated by the solid line in the figure is formed.

Further, the pocket region 66, extension region 67, second sidewall 64, shallow first source/drain region 68 and third sidewall 65, which are indicated by the broken line in the figure, are sequentially formed within the silicon substrate 60 of which the surface is exposed after the removal of the sidewalls. At this time, the second and third sidewalls 64 and 65 may be formed by a film other than the carbon-containing silicon nitride oxide film. However, when performing the silicification or the formation of the silicon germanium layer 70 as shown in FIG. 36 in the subsequent steps, it is desired that at least the third sidewall 65 is formed by the carbon-containing silicon nitride oxide film.

In the example of FIG. 37, the sidewalls formed outside the first sidewall 63 can be configured using the silicon oxide film. However, the innermost first sidewall 63 is formed using the carbon-containing silicon nitride oxide film. As a result, even after the outside sidewalls are removed by the HF treatment, corrosion in the gate insulating film 61 due to the HF solution is prevented by the inside first sidewall 63 during the HF treatment, so that the stable transistor characteristics can be obtained.

Further, according to this method, more specifically, according to the method for forming the second source/drain region 69 and then forming each impurity region of the pocket region 66, the extension region 67 and the first source/drain region 68, a distribution of the impurity regions or sizes of the first, second and third sidewalls 63, 64 and 65 can be controlled with higher accuracy. For example, when forming a CMOS structure, the first, second and third sidewalls 63, 64 and 65 having appropriate sizes can be formed in response to each impurity seed or annealing temperature on the p MOS transistor side and on the n MOS transistor side, or in response to demand characteristics of each of the p MOS transistor and the n MOS transistor.

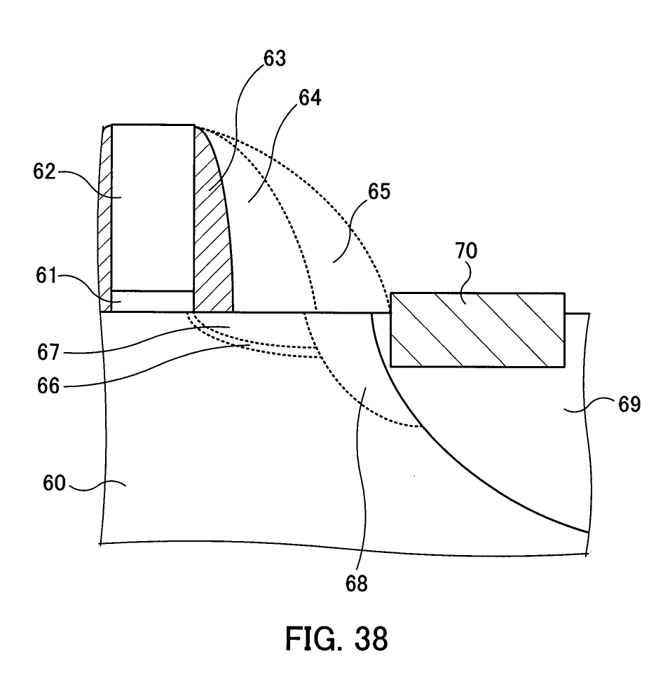

In the example shown in FIG. 38, speeding up of the transistor is realized by using the silicon germanium layer 70, in the same manner as in the example shown in FIG. 36. However, the formation method thereof is different. More specifically, in the example, the first sidewall 63 is first formed by the carbon-containing silicon nitride oxide film. Then, sidewalls having shapes corresponding to those of the second and third sidewalls 64 and 65 are formed outside the first sidewall 63. The sidewalls formed outside the first sidewall 63 may have either the single layer structure or the double structure. Further, the sidewalls may be formed by a film other than the carbon-containing silicon nitride oxide film, for example, the silicon oxide film.

Using these sidewalls as masks, the deep second source/drain region 69 is first formed within the silicon substrate 60. Then, a trench is formed within the second source/drain region 69. Next, the trench is subjected to the HF treatment to remove the outside second and third sidewalls 64 and 65 and to clean the exposed surface of the trench inside wall. Then, the silicon germanium layer 70 is formed within the trench by the epitaxial growth. Through the previous steps, the structure indicated by the solid line in the figure is formed.

Further, the pocket region 66, extension region 67, second sidewall 64, shallow first source/drain region 68 and third sidewall 65, which are indicated by the broken line in the figure, are sequentially formed within the silicon substrate 60. At this time, the second and third sidewalls 64 and 65 may be formed by a film other than the carbon-containing silicon nitride oxide film. However, when performing the silicification in the subsequent steps, it is desired that at least the third sidewall 65 is formed by the carbon-containing silicon nitride oxide film.

In the example shown in FIG. 38, the carbon-containing silicon nitride oxide film is used for the first sidewall 63 and therefore, corrosion in the gate insulating film 61 due to the HF solution is prevented. At the same time, the silicon germanium layer 70 is formed and therefore, speeding up of the transistor can be realized. Further, each impurity region of the pocket region 66, the extension region 67 and the first source/drain region 68 is formed after forming the second source/drain region 69 and therefore, a distribution of the impurity regions or sizes of the first, second and third sidewalls 63, 64 and 65 can be controlled with high accuracy. As a result, the highly stable transistor characteristics can be obtained.

As described above, the carbon-containing silicon nitride oxide film capable of being formed at a low temperature using BTBAS and oxygen as starting materials has high HF resistance, high etching selectivity and preferable film formation property. Therefore, the film can be preferably used for construction materials for semiconductor devices, in particular, construction materials for sidewalls. When using this carbon-containing silicon nitride oxide film for the semiconductor device, the transistor characteristics are enhanced and stabilized, so that high performance and high quality in the semiconductor device can be realized.

In the examples shown in FIGS. 33 to 38, the film thicknesses in the formation of each constituent element or the sizes after the formation thereof and the formation conditions thereof can be arbitrarily set according to the shape of the semiconductor device to be formed. For example, those can be set similarly to those exemplified in FIGS. 14 to 32.

In the above description, a case is described where the carbon-containing silicon nitride oxide film is used for the sidewall of the gate electrode. Of course, the carbon-containing silicon nitride oxide film may also be used for the construction materials for other components within the semiconductor device.

In the present invention, the sidewall is formed by using the carbon-containing silicon nitride oxide film and therefore, the recession of the sidewall during the cleanup can be suppressed and the reduction in the fringe capacitance can be realized. Further, this carbon-containing silicon nitride oxide film can be formed under low temperature conditions and therefore, unnecessary impurity diffusion can be suppressed. As a result, the transistor characteristics are enhanced and stabilized, so that high performance and high quality in the semiconductor device can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for manufacturing a semiconductor device having a gate electrode, and a sidewall provided on the gate electrode, comprising the steps of:
forming the gate electrode on a semiconductor substrate through a gate insulating film,
forming one sidewall on a part that comes in contact with a side wall of the gate electrode,
forming other sidewalls on a part that is outside the one sidewall and that serves as a surface of the one sidewall, and
introducing impurities into the semiconductor substrate using the other sidewalls as masks to form an impurity region within the substrate,
wherein among the one sidewall and the other sidewalls, at least the other sidewalls are formed using a carbon-containing silicon nitride oxide film.

2. The method for manufacturing a semiconductor device according to claim 1, wherein in the step of forming the one sidewall on the part that comes in contact with the side wall of the gate electrode, when the one sidewall is formed using the carbon-containing silicon nitride oxide film, the one sidewall is formed on the part that comes in contact with the side wall of the gate insulating film, as well as on the part that comes in contact with the side wall of the gate electrode.

3. The method for manufacturing a semiconductor device according to claim 1, wherein the carbon-containing silicon nitride oxide film is formed by a CVD method using bis (tertiarybutylamino) silane and oxygen.

4. The method for manufacturing a semiconductor device according to claim 1, wherein the carbon-containing silicon nitride oxide film is formed by a CVD method using bis (tertiarybutylamino) silane and nitrous oxide.

5. The method for manufacturing a semiconductor device according to claim 1, wherein the carbon-containing silicon nitride oxide film is formed by a CVD method using bis (tertiarybutylamino) silane and nitrogen monoxide.

6. The method for manufacturing a semiconductor device according to claim 1, further comprising the steps of:
cleaning surfaces of the gate electrode and the impurity region, and
subjecting the cleaned surfaces of the gate electrode and the impurity region to silicification, after the step of introducing impurities into the semiconductor substrate using the other sidewalls as masks to form the impurity region within the substrate, the other sidewalls being formed using the carbon-containing silicon nitride oxide film.

7. The method for manufacturing a semiconductor device according to claim 1, further comprising the steps of:
forming a trench within the impurity region,
cleaning an inside wall of the trench, and
forming in the cleaned trench a semiconductor layer having a lattice constant different from that of the semiconductor substrate, after the step of introducing impurities into the semiconductor substrate using the other sidewalls as masks to form the impurity region within the substrate.

8. A method for manufacturing a semiconductor device having a gate electrode and a sidewall provided on the gate electrode, comprising the steps of:
forming the gate electrode on a semiconductor substrate through a gate insulating film,
forming one sidewall on a part that comes in contact with a side wall of the gate electrode using a carbon-containing silicon nitride oxide film,
forming other sidewalls outside the one sidewall, and
introducing impurities into the semiconductor substrate using the other sidewalls as masks to form an impurity region within the substrate.

9. The method for manufacturing a semiconductor device according to claim 8, wherein in the step of forming the one sidewall on the part that comes in contact with the side wall of the gate electrode using the carbon-containing silicon nitride oxide film, the one sidewall is formed on the part that comes in contact with the side wall of the gate insulating film, as well as on the part that comes in contact with the side wall of the gate electrode.

10. A method for manufacturing a semiconductor device having a gate electrode and a sidewall provided on the gate electrode, comprising the steps of:
forming the gate electrode on a semiconductor substrate through a gate insulating film,
forming a silicon oxide film on the whole surface of the semiconductor substrate,
forming a carbon-containing silicon nitride oxide film on the silicon oxide film,
etching the silicon oxide film and the carbon-containing silicon nitride oxide film to form sidewalls on both sides of the gate electrode, and
introducing impurities into the semiconductor substrate using the sidewalls as masks to form an impurity region within the substrate.

11. The method for manufacturing a semiconductor device according to claim 10, wherein in the step of forming the silicon oxide film on the whole surface of the semiconductor substrate and in the step of forming the carbon-containing silicon nitride oxide film on the silicon oxide film, the same starting materials are used for the formation of the silicon oxide film and the formation of the carbon-containing silicon nitride oxide film and wherein after the formation of the silicon oxide film, a starting material composition is changed to successively form the carbon-containing silicon nitride oxide film.

12. A semiconductor device, comprising:
a gate electrode, and
a sidewall provided on the gate electrode,
wherein the sidewall is formed using a carbon-containing silicon nitride oxide film and the carbon-containing silicon nitride oxide film is formed on at least a part serving as a surface of the sidewall.

13. The semiconductor device according to claim 12, wherein the carbon-containing silicon nitride oxide film contains a carbon atom in the range of 3 to 20 atomic %.

14. The semiconductor device according to claim 12, wherein in the case where the semiconductor device has a CMOS structure, the sidewall is formed such that a sidewall on a p MOS side where impurities are introduced has almost the same shape as that on an n MOS side where impurities are introduced.

15. The semiconductor device according to claim 12, which has a structure that the gate electrode having formed thereon the sidewall is connected to a source/drain region of another transistor which is configured on the same semiconductor substrate as a transistor having the gate electrode.

16. The semiconductor device according to claim 12, further comprising an impurity region formed by introducing, using the sidewall as a mask, impurities into a semiconductor substrate having formed thereon the gate electrode, wherein a semiconductor layer having a lattice constant different from that of the semiconductor substrate is formed within the impurity region.

17. The semiconductor device according to claim 16, wherein the semiconductor substrate is a silicon substrate and the semiconductor layer is a silicon germanium layer containing impurities.

18. A semiconductor device, comprising:
a gate electrode, and
a sidewall provided on the gate electrode,
wherein the sidewall is formed using a carbon-containing silicon nitride oxide film and the carbon-containing silicon nitride oxide film is formed only on a part of the sidewall in contact with a side wall of the gate electrode.

19. The semiconductor device according to claim 18, wherein the carbon-containing silicon nitride oxide film is formed on a part that comes in contact with a side wall of a gate insulating film provided between the gate electrode and a semiconductor substrate on which the gate electrode is formed, as well as on the part that comes in contact with the side wall of the gate electrode.

20. The semiconductor device according to claim 18, wherein the carbon-containing silicon nitride oxide film contains a carbon atom in a range of 3 to 20 atomic %.
